(19) United States
(12) Patent Application Publication
(10) Pub. No.: US 2019/0250206 A1
(43) Pub. Date: Aug. 15, 2019

(54) FAILURE DIAGNOSIS SYSTEM

(71) Applicant: Koki Holdings Co., Ltd., Tokyo (JP)

(72) Inventors: Yuta NOGUCHI, Ibaraki (JP); Yuki HORIE, Ibaraki (JP); Kazuhiko FUNABASHI, Ibaraki (JP)

(73) Assignee: Koki Holdings Co., Ltd., Tokyo (JP)

(21) Appl. No.: 16/320,100

(22) PCT Filed: Jul. 28, 2017
(86) PCT No.: PCT/JP2017/027471

§ 371 Date: Jan. 24, 2019

(30) Foreign Application Priority Data
Aug. 31, 2016 (JP) 2016-169632
Oct. 14, 2016 (JP) 2016-202899

(51) Int. Cl. G01R 31/28; B25F 5/00; G06Q 10/00

(52) U.S. Cl. CPC G01R 31/2825; B25D 16/006; G06Q 10/20; B25F 5/00

(57) ABSTRACT

The failure diagnosis system is provided with an electric tool 1, and a diagnosis device 100 that can be connected with the electric tool 1. The diagnosis device 100 reads the usage history information of the electric tool 1 from the electric tool 1 to which the diagnosis device 100 has been connected, estimates a failure part of the electric tool 1 on the basis of the usage history information, and reports information indicating the failure part. The usage history information includes at least one of the motor operation time, the number of operations of a motor driving switch, the power supply voltage, a motor current, the motor temperature, the temperature of a motor driving circuit, whether or not the motor can be driven, the presence or absence of a high-temperature abnormality, the presence or absence of an overcurrent abnormality, and the presence or absence of an overvoltage abnormality.

### TECHNICAL FIELD

The present invention relates to a failure diagnosis system that diagnoses a failure of an electric tool and a management system that manages an instrument such as an electric tool having a communication function, a battery pack, or a charger.

### BACKGROUND ART

In the construction of the structure, exterior, and interior of a residential building, electric tools are widely used. The following Patent Literature 1 discloses a diagnosis system that diagnoses deterioration or failure of an electric tool. This diagnosis system is used to determine the deterioration status of an electric tool on the basis of a cumulative value for a driving time of an electric tool or to determine the presence or absence of a failure of an electric tool on the basis of a motor current value using a holding table for holding the electric tool at times other than during work. On the other hand, an operator may possess a plurality of electric tools, and thus the management of a plurality of electric tools using a network is proposed.

### CITATION LIST

### Patent Literature

[Patent Literature 1]

Japanese Unexamined Patent Application Publication No. 2009-83043

[Patent Literature 2]

Japanese Unexamined Patent Application Publication No. 2000-334670

### SUMMARY OF INVENTION

### Technical Problem

The diagnosis system of Patent Literature 1 determines the presence or absence of a failure, and displays that repair is required in a case of a failure being determined, but does not display information relating to a failure part. On the other hand, there are an increasing number of electric tools having a brushless motor as a driving source mounted thereon, and such electric tools have a large number of parts in an electronic circuit and around the circuit. Thereby, a failure part is not likely to be found during a failure, and it is very difficult to conjecture and identify a cause of failure. Therefore, there is a problem in that the time and costs required for repair may become excessive due to replacement or the like of a part which is not out of order.

Patent Literature 2 discloses an electric tool control system in which screw fastening information of each of a plurality of electric tools is transmitted from a central device to respective electric tools through a network, to thereby centrally manage screw fastening of the plurality of electric tools in the central device. However, since fastening information of each electric tool is just stored in a storage unit of the electric tool, the information of each electric tool is not able to be checked in the central device.

The present invention is contrived in view of such circumstances, and an objective thereof is to provide a failure diagnosis system that allows for easier identification of a failure part of an electric tool than in the related art.

Another objective of the present invention is to provide a management system that makes it possible to manage more information and to share information between operators by storing information of an instrument including an electric tool or a battery pack in other than a storage unit of the instrument and performing the management thereof. Further, an objective is to provide a management system that makes it possible to share up-to-date information at all times during access from anywhere by collectively managing all pieces of information for each instrument.

### Solution to Problem

According to a first aspect of the present invention, there is provided a failure diagnosis system including: an electric tool having a function of storing usage history information thereof; and a diagnosis device capable of being connected to the electric tool, wherein the diagnosis device reads out the usage history information of the electric tool from a connected electric tool, estimates a failure part of the electric tool on the basis of the usage history information, and reports information indicating the failure part.

The usage history information may include at least one of a motor operation time, the number of operations of a motor driving switch, a power supply voltage, a motor current, a motor temperature, a temperature of a motor driving circuit, whether or not a motor is able to be driven, presence or absence of a high-temperature abnormality, presence or absence of an overcurrent abnormality, and presence or absence of an overvoltage abnormality.

The electric tool may include a brushless motor, an inverter circuit for electrical conduction to the brushless motor, and a control unit that controls the inverter circuit.

The electric tool may include a sensor that detects a rotational position of the brushless motor, and the usage history information may include a history of an output signal of the sensor.

The diagnosis device may estimate the inverter circuit to be out of order in a case where the usage history information indicates that the brushless motor is not able to be driven, an overcurrent abnormality is present, and a motor operation time exceeds a predetermined time.

The diagnosis device may estimate the filter circuit to be out of order in a case where the electric tool is AC-driven and has a filter circuit, and a case where the usage history information indicates that the brushless motor is able to be driven and an overvoltage abnormality is present.

The diagnosis device may display a button for a user to give an instruction for starting of diagnosis for a connected electric tool on a screen.

The diagnosis device may display product information, presence or absence of a failure, and a failure estimation part of a connected electric tool on a screen.

The diagnosis device may display a cause of a defect in a connected electric tool on a screen.

The diagnosis device may display usage history information of a connected electric tool on a screen.

The electric tool may have a connector for cable connection to the diagnosis device which faces outside from a housing thereof.

The diagnosis device may be capable of being wirelessly connected to the electric tool.

The diagnosis device may be a general-purpose computer.

According to a second aspect of the present invention, there is provided a management system including: an instrument having a first storage unit that stores first information; a management device having a second storage unit that stores the first information stored in the first storage unit, and stores second information different from the first information; and a control unit that reads out at least one of the first information and the second information stored in the second storage unit through a network, and displays the read-out information on a display screen.

Note that any combination of the foregoing components, and those obtained by converting the representation of the present invention between a method, a system and the like are also effective as aspects of the present invention.

### Advantageous Effects of Invention

According to the first aspect of the present invention, it is possible to provide a failure diagnosis system that allows for easier identification of a failure part of an electric tool than in the related art.

According to the second aspect of the present invention, it is possible to provide a management system that makes it possible to manage more information and to share the information between operators. In addition, since the management system can be accessed from any sales shop or the like, it is possible to provide a management system that makes it possible to share up-to-date information at all times.

### BRIEF DESCRIPTION OF DRAWINGS

FIG. 1 is a circuit block diagram of an AC driving electric tool 1 in Embodiment 1 of the present invention.

FIG. 2 is a circuit block diagram of a failure diagnosis system according to Embodiment 1, and is a circuit block diagram in an interconnection state between the electric tool 1 and a diagnosis device 100.

FIG. 3 is an appearance diagram of the failure diagnosis system according to Embodiment 1, and is a diagram illustrating connection between a main board 60 of the electric tool 1 and the diagnosis device 100.

FIG. 4 is a plan view of the main board 60.

FIG. 5 is a side view in a state where a rubber cap 64a of a connector 64 of the main board 60 is covered.

FIG. 6 is a diagram illustrating connection between a large number of diagnosis devices 100 and a server 200.

FIG. 7 is a flowchart illustrating a flow of a diagnosis in the diagnosis device 100.

FIG. 8 is a flowchart illustrating a specific example of details of “analysis and diagnosis” (S7) in FIG. 7.

FIG. 9 is a flowchart illustrating a flow in a case where a diagnosis is performed by the diagnosis device 100 while a motor 31 of the electric tool 1 is rotated.

FIG. 10 is a diagram illustrating abnormality determinations of Hall ICs for rotation detection of the motor 31.

FIG. 11 is a diagnosis table illustrating an example of a relationship between usage history information of the electric tool 1 and a diagnosis result (estimated failure part).

FIG. 12 is a diagram illustrating display of an initial screen of a failure diagnosis application which is displayed on an output device 104 by the diagnosis device 100.

FIG. 13 is a diagram illustrating display in a case where a diagnosis result in the application is normal.

FIG. 14 is a diagram illustrating display in a case where a diagnosis result in the application is abnormal.

FIG. 15 is a circuit block diagram a DC driving electric tool 2 in Embodiment 1.

FIG. 16 is a cross-sectional side view of a working machine 10a which is an example of the AC driving electric tool 1.

FIG. 17 is an example of a configuration diagram illustrating Embodiment 2 of a management system of the present invention.

FIG. 18 is an example of a schematic diagram illustrating Embodiment 2 of the management system of the present invention.

FIG. 19 is another example of a schematic diagram illustrating Embodiment 2 of the management system of the present invention.

FIG. 20 is a control flowchart of an intermediate device.

FIG. 21 is a control flowchart of an instrument.

FIG. 22 is an example of a display screen of the intermediate device.

FIG. 23 is an example of a display screen of the intermediate device.

FIG. 24 is an example of a display screen of the intermediate device.

FIG. 25 is an example of a display screen of the intermediate device.

FIG. 26 is a control flowchart of the intermediate device.

FIG. 27 is an example of a display screen of the intermediate device.

FIG. 28 is an example of a display screen of the intermediate device.

FIG. 29 is a schematic diagram illustrating Embodiment 3 of the management system of the present invention.

### DESCRIPTION OF EMBODIMENTS

Hereinafter, preferred embodiments of the present invention will be described in detail with reference to the accompanying drawings. Meanwhile, identical or equivalent components, members, processes, and the like illustrated in the drawings are denoted by the same reference numerals and signs, and duplicated description thereof is suitably omitted. In addition, the embodiments are not intended to limit the invention but are merely illustrative, and all features described in the embodiments or combinations thereof are not necessarily essential to the invention.

### Embodiment 1

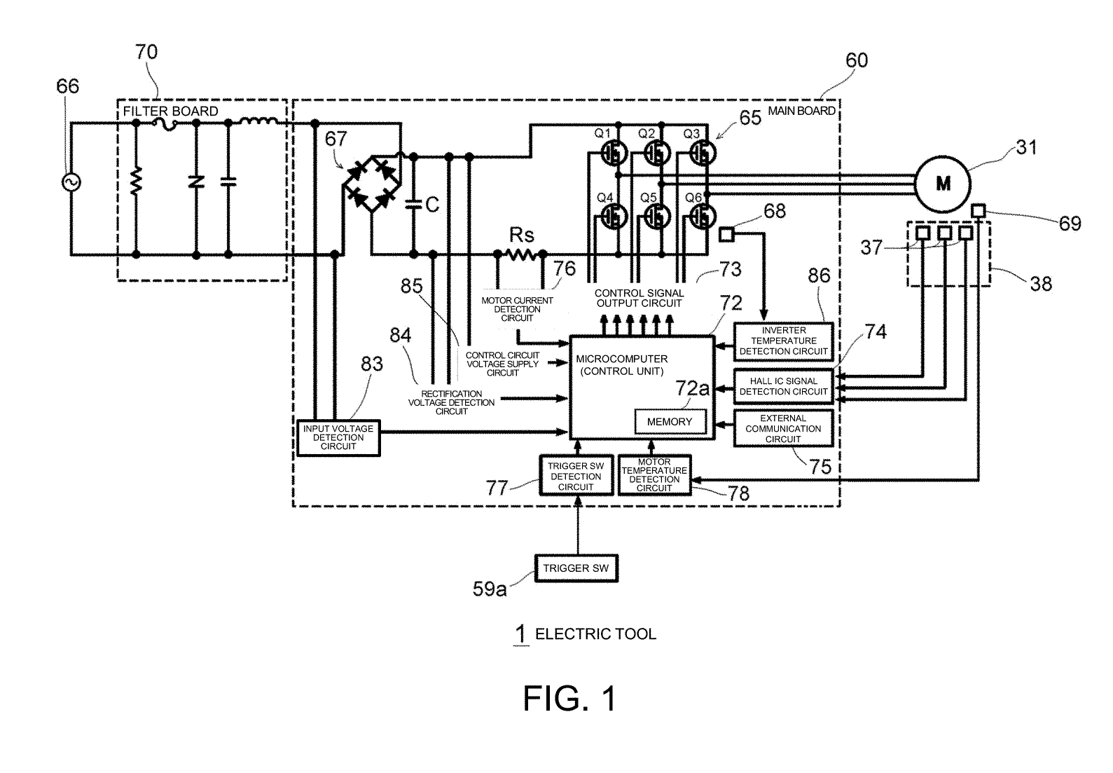

FIG. 1 is a circuit block diagram of an AC driving electric tool 1 in Embodiment 1 of the present invention. The electric tool 1 is a corded electric tool operating by receiving supply of power from an external AC power supply 66. In the electric tool 1, a filter board 70 is connected to the AC power supply 66. A filter circuit provided in the filter board 70 has a role of noise removal or surge absorption. The output voltage of the filter circuit is rectified by a diode bridge 67 as a rectifying circuit, and is smoothed by a capacitor C. An input voltage to the diode bridge 67 is detected by an input voltage detection circuit 83, and is transmitted to a microcomputer 72 as a control unit. A voltage rectified and smoothed by the diode bridge 67 and the capacitor C is detected by a rectification voltage detection circuit 84, and is transmitted to the microcomputer 72. A control circuit voltage supply circuit 85 converts the voltage rectified and smoothed by the diode bridge 67 and the capacitor C into a voltage (for example, DC 5 V) for operation of the microcomputer 72.

An inverter circuit 65 composed of switching elements Q1 to Q6 such as FETs or IGBTs on which three-phase bridge connection is performed switches the voltage rectified and smoothed by the diode bridge 67 and the capacitor C, and supplies a driving current to a motor 31. The switching control (for example, PWM control) of the switching elements Q1 to Q6 is performed by a control signal output circuit 73 which is controlled by the microcomputer 72. The driving current of the motor 31 is a converted into a voltage by a sensing resistor Rs, is detected by a motor current detection circuit 76 having received the voltage, and is transmitted to the microcomputer 72. The temperature of the inverter circuit 65 (switching elements Q1 to Q6) is converted into a voltage by a temperature detection element 68 such as a thermistor disposed in the vicinity of the inverter circuit 65, is detected by an inverter temperature detection circuit 86, and is transmitted to the microcomputer 72.

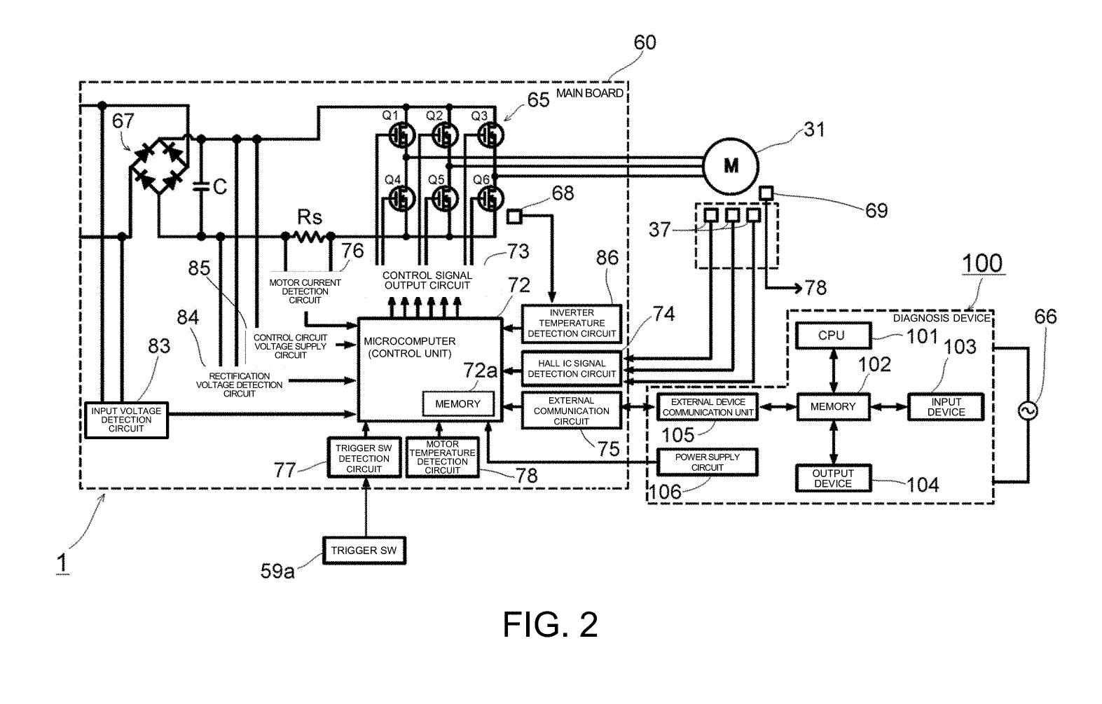

The motor 31 is a brushless motor herein. The rotational position (rotor rotational position) of the motor 31 is detected by three Hall ICs 37 as sensors provided in a Hall IC board 38. Specifically, the output voltage of each of the Hall ICs 37 varying with the rotation of a rotor is detected by a Hall IC signal detection circuit 74, and is transmitted to the microcomputer 72. The microcomputer 72 detects the rotational position of the rotor. The temperature of the motor 31 is converted into a voltage by a temperature detection element 69 such as a thermistor disposed in the vicinity of the motor 31, is detected by a motor temperature detection circuit 78, and is transmitted to the microcomputer 72. A trigger switch 59a is a switch for a user to control the driving and stopping of the motor 31. Turning on and turning off of the trigger switch 59a is detected by a trigger switch detection circuit 77, and is transmitted to the microcomputer 72. An external communication circuit 75 is a circuit for communication (connection) with a diagnosis device 100 (FIG. 2) described later through cable communication using a universal serial bus (USB) or the like, or wireless communication such as Wi-Fi, Bluetooth (Registered Trademark), or Zigbee (Registered Trademark).

The microcomputer 72 operates with a voltage supplied from the control circuit voltage supply circuit 85, drives the control signal output circuit 73 in accordance with a user's operation of the trigger switch 59a to control the inverter circuit 65, and drives the motor 31. In a case where the microcomputer 72 detects an abnormality such as an overcurrent or an overvoltage, and a high temperature of the motor 31 or a high temperature of the inverter circuit 65, the microcomputer 72 stops driving the motor 31. The microcomputer 72 includes a memory 72a as a storage unit, and stores usage history information of the electric tool 1 in the memory 72a. The usage history information includes the operation time of the motor 31, the number of operations of the trigger switch 59a, a power supply voltage (voltage on the input side and voltage on the output side of the diode bridge 67), the current of the motor 31, the temperature of the motor 31, the temperature of the inverter circuit 65, the advisability of driving of the motor 31, the presence or absence of a high-temperature abnormality, the presence or absence of an overcurrent abnormality, and the presence or absence of an overvoltage abnormality.

FIG. 2 is a circuit block diagram of a failure diagnosis system according to Embodiment 1, and is a circuit block diagram in an interconnection state between the electric tool 1 and the diagnosis device 100. In FIG. 2, the filter board 70 of the electric tool 1 is not shown in the drawing. The diagnosis device 100 is a general-purpose computer such as a personal computer, and includes a central processing unit (CPU) 101 as a control unit, a memory 102 as a storage unit, an input device 103 such as a keyboard or a touch pad, an output device 104 such as a monitor (display), an external device communication unit 105, and a power supply circuit 106. The memory 102 stores (memorizes) a failure diagnosis program described later. In addition, the memory 102 may store the type and model name of an electric tool which is a target for diagnosis, and diagnosis conditions according thereto. The input device 103 functions as an operating unit for a user to execute the failure diagnosis program. The output device 104 performs screen display relating to the failure diagnosis program. The external device communication unit 105 has a role of communicating with the electric tool 1 through cable communication using a USB or the like, or wireless communication such as Wi-Fi, Bluetooth (Registered Trademark), or Zigbee (Registered Trademark). The power supply circuit 106 is a circuit for supplying an operating voltage to the microcomputer 72 of the electric tool 1. Meanwhile, the diagnosis device 100 may be driven by the external AC power supply 66, and may be driven by a battery.

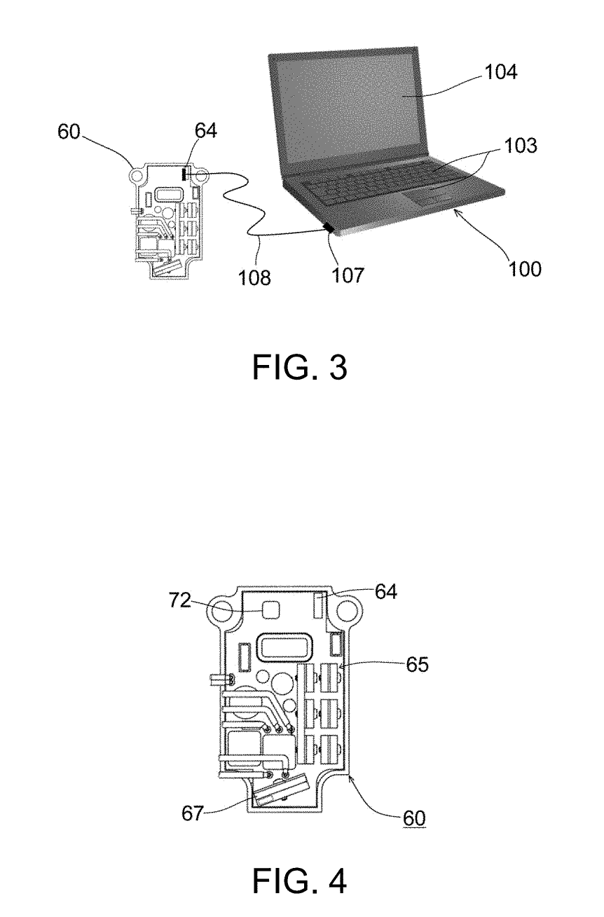

FIG. 3 is an appearance diagram of the failure diagnosis system according to Embodiment 1, and is a diagram illustrating connection between a main board 60 of the electric tool 1 and the diagnosis device 100. Meanwhile, in FIG. 3, in order to make the connection easier to understand, the electric tool 1 is not shown in the drawing except the main board 60, but the main board 60 is not required to be separated from the electric tool 1, and diagnosis is able to be performed thereon in a state where the main board 60 is incorporated into the electric tool 1. The example of FIG. 3 is an example of cable connection, and a connector 64 provided on the main board 60 and a connector 107 of the diagnosis device 100 are connected to each other by a cable 108. The cable 108 is, for example, a USB cable, which makes it possible to perform communication between the main board 60 and the diagnosis device 100, and supplies power from the diagnosis device 100 to the main board 60. Meanwhile, the connector 64 may be extracted so as to face outside from the housing of the electric tool 1. In this case, the electric tool 1 can be connected to the diagnosis device 100 without performing work such as, for example, detachment of one of housings having a two-division structure.

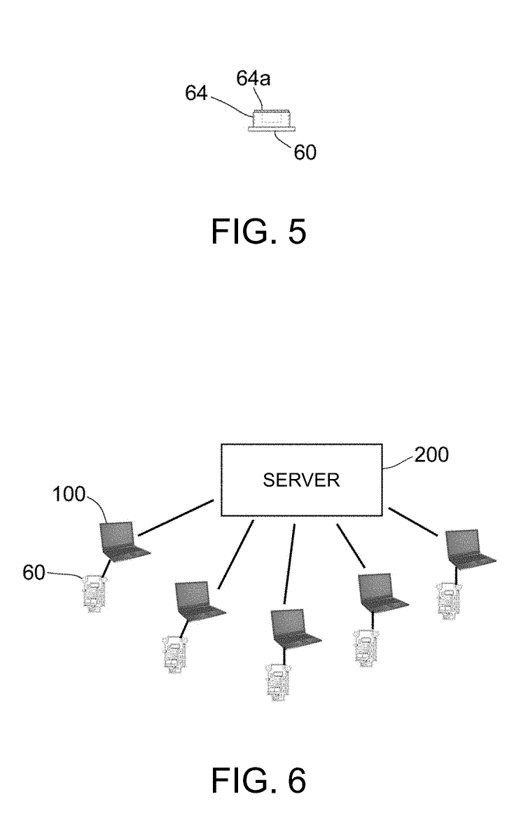

FIG. 4 is a plan view of the main board 60. The connector 64, the inverter circuit 65, the diode bridge 67, the microcomputer 72, and each circuit part included in the broken line of the main board 60 in FIG. 1 are mounted in the main board 60. Meanwhile, the main board 60 is not required to be one board, and may be configured such that the function of the main board 60 is realized by a plurality of boards. It is preferable that the connector 64 is covered by a rubber cap 64a as a cover member as shown in FIG. 5 from the viewpoint of dust proofing or the like, when not connected to the diagnosis device 100 (during non-diagnosis).

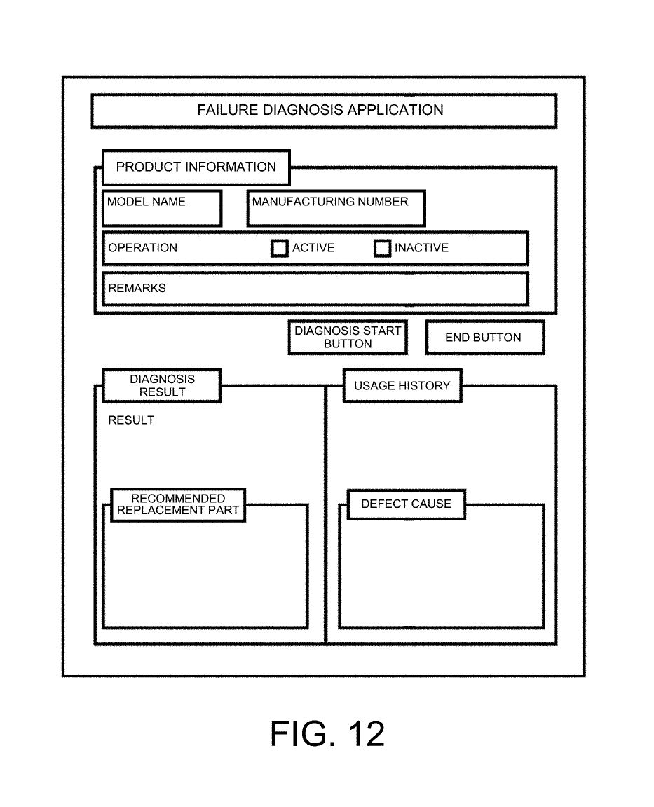

FIG. 6 is a diagram illustrating connection between a large number of diagnosis devices 100 and a server 200. The server 200 is connected to a large number of diagnosis devices 100 using a network such as the Internet, and can accumulate diagnosis results from the large number of diagnosis devices 100 in a database. According to this, information useful to product development can be centrally managed, which leads to convenience. Meanwhile, in a case where information accumulated in the server 200 is displayed on the output device 104 of the diagnosis device 100, a data readout button is provided on an input screen (see FIG. 12) by starting up a diagnosis application described later, and the data readout button may be operated after a model name and a manufacturing number are input.

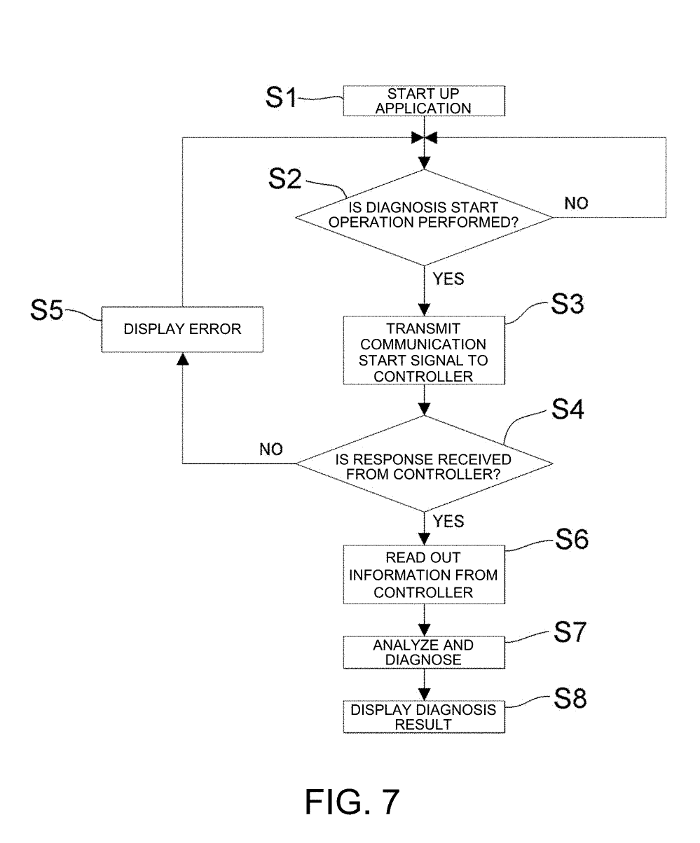

FIG. 7 is a flowchart illustrating a flow of a diagnosis in the diagnosis device 100. In a case where the startup operation of a diagnosis program (diagnosis application) is performed according to a user's operation of the input device 103, the CPU 101 loads the diagnosis program from the memory 102, and starts up the diagnosis program (S1). In a case where a diagnosis start operation is performed according to the input device 103 (YES in S2), the CPU 101 transmits a communication start signal to the microcomputer 72 (controller) of the electric tool 1 (S3). In a case where a response to the communication start signal is not received from the microcomputer 72 of the electric tool 1 (NO in S4), the CPU 101 performs error display on the output device 104 (S5). The error display herein may be display indicating that the electric tool 1 is a type having no microcomputer 72, or display indicating that the microcomputer 72 of the electric tool 1 has a possibility of being out of order. In a case where a response to the communication start signal is received from the microcomputer 72 of the electric tool 1 (YES in S4), the CPU 101 reads out the usage history information of the electric tool 1 from the microcomputer 72 (S6), diagnoses the presence or absence of a failure of the electric tool 1 by analyzing the usage history information (S7), and displays a diagnosis result on the output device 104 to report the diagnosis result to a user (S8).

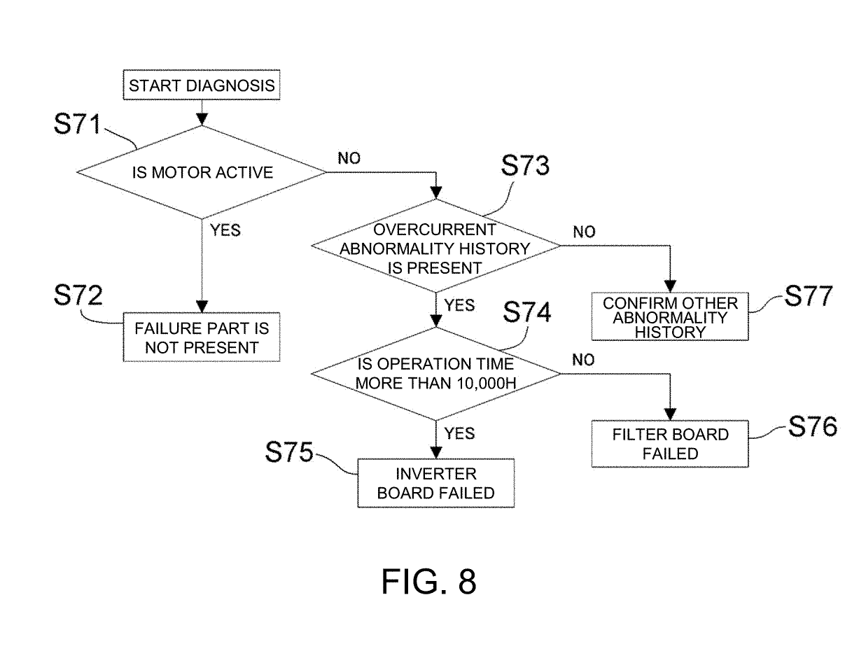

FIG. 8 is a flowchart illustrating a specific example of details of “analysis and diagnosis” (S7) in FIG. 7. In a case where the usage history information indicates that the motor 31 of the electric tool 1 is active (YES in S71), the CPU 101 diagnoses a failure part as not being present (S72). In a case where the usage history information indicates that the motor 31 of the electric tool 1 is not active (NO in S7), the CPU 101 confirms the presence or absence of an overcurrent abnormality (S73). In a case where an overcurrent abnormality is included in the usage history information (YES in S73), the CPU 101 confirms the cumulative operation time of the motor 31 (S74). In a case where the cumulative operation time of the motor 31 in the usage history information is equal to or greater than a predetermined time (for example, 10,000 hours) (YES in S74), the CPU 101 diagnoses a failure of the inverter circuit 65 (inverter board) as being present (S75). Meanwhile, in the present embodiment, the inverter board is included in the main board 60, which results in a failure of the main board 60. In a case where the cumulative operation time of the motor 31 in the usage history information is not equal to or greater than the predetermined time (NO in S74), the CPU 101 diagnoses a failure of the filter board 70 as being present (S76). In a case where an overcurrent abnormality is not included in the usage history information in step S73 (NO in S73), the CPU 101 confirms other abnormality history (S77).

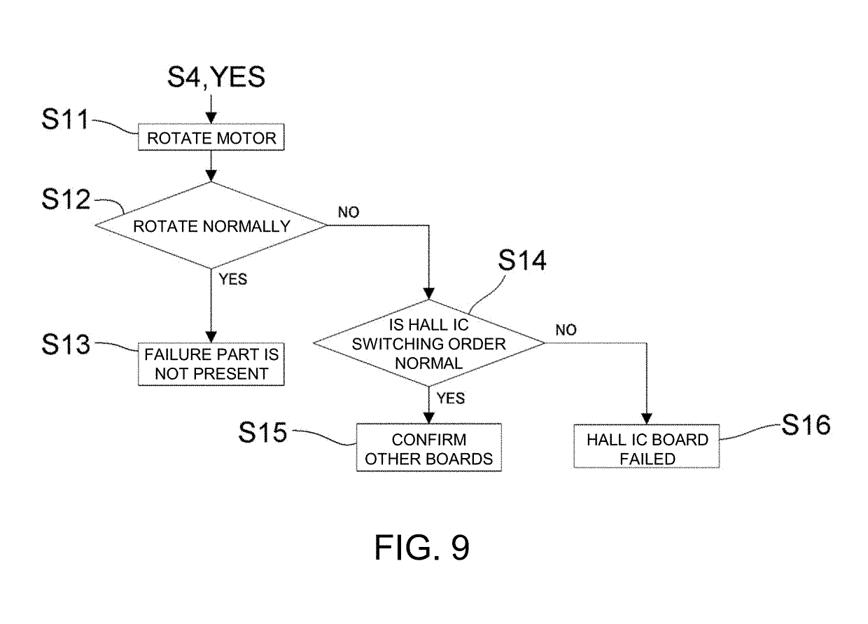

FIG. 9 is a flowchart illustrating a flow in a case where a diagnosis is performed by the diagnosis device 100 while the motor 31 of the electric tool 1 is rotated. In this flowchart, the electric tool 1 is connected to the AC power supply 66, and a diagnosis is performed while confirming whether the motor 31 is actually active. In a case where a response to the communication start signal is received from the microcomputer 72 in step S4 of FIG. 7 (YES in S4), the CPU 101 controls the microcomputer 72 such that the motor 31 is rotated (S11). Here, instead of rotating the motor 31 by the CPU 101 controlling the microcomputer 72, a user may be prompted to operate the trigger switch 59a of the electric tool 1 through display on the output device 104 or the like. In a case where the motor 31 rotates normally (YES in S12), the CPU 101 diagnoses a failure part as not being present (S13). In a case where the motor 31 does not rotate normally (NO in S12), the CPU 101 confirms whether the order of output switching of the Hall ICs 37 is normal (S14). In a case where the order of output switching of the Hall ICs 37 is normal (YES in S14), the CPU 101 confirms the presence or absence of a failure with respect to boards other than the Hall IC board 38, as in step S73 of FIG. 8 and the subsequent steps (S15). In a case where the order of output switching of the Hall ICs 37 is not normal (NO in S14), the CPU 101 diagnoses a failure of the Hall IC board 38 as being present (S16).

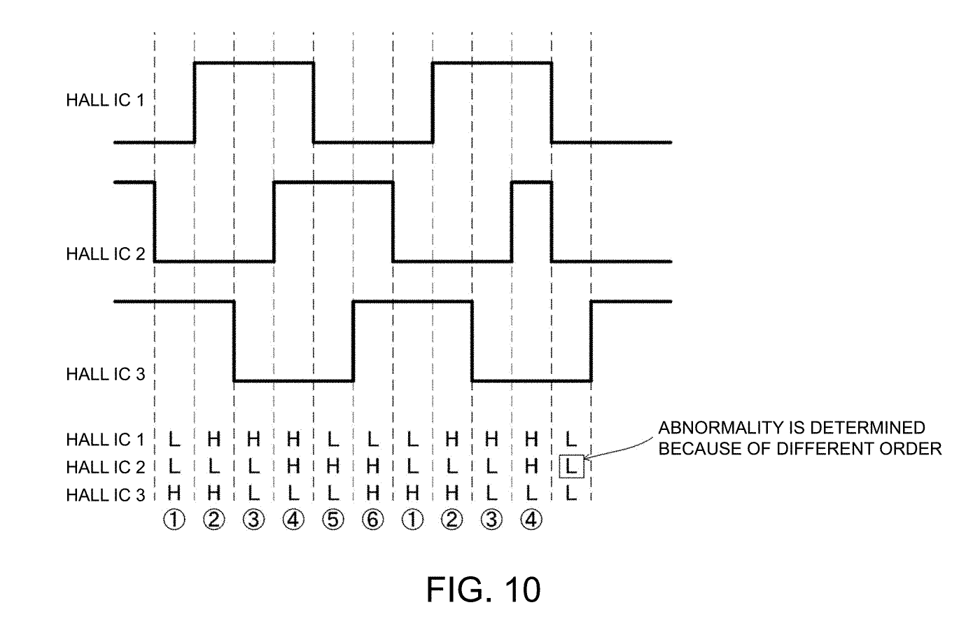

FIG. 10 is a diagram illustrating abnormality determinations of Hall ICs for rotation detection of the motor 31. In FIG. 10, three Hall ICs 37 are assigned numbers of 1 to 3, respectively, to make a distinction therebetween. In the example of FIG. 10, since an order abnormality occurs in the output of a second Hall IC, the CPU 101 diagnoses a failure of the Hall IC board 38 as being present.

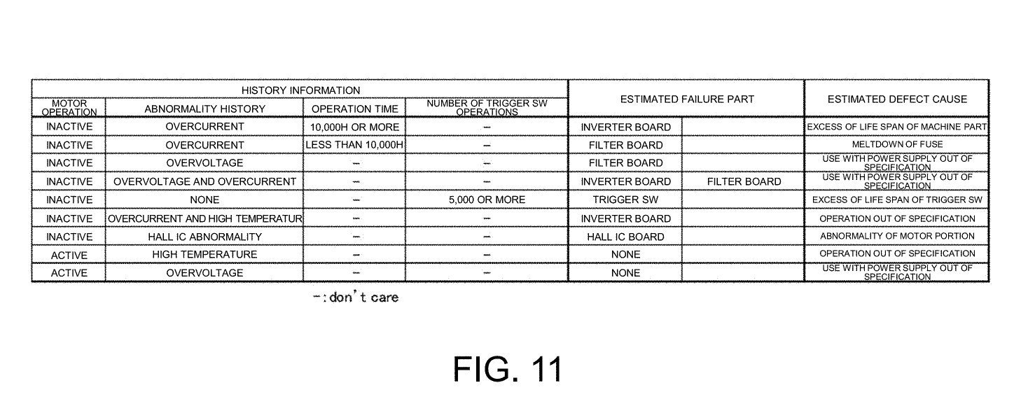

FIG. 11 is a diagnosis table illustrating an example of a relationship between the usage history information of the electric tool 1 and a diagnosis result (estimated failure part). In the example of FIG. 11, in a case where the motor 31 is not active, an overcurrent abnormality is included in the usage history information, and the cumulative operation time of the motor 31 is equal to or greater than 10,000 hours, the CPU 101 estimates a failure part to be an inverter board, and estimates a defect cause to be the life span of a machine part being exceeded. In a case where the motor 31 is not active, an overcurrent abnormality is included in the usage history information, and the cumulative operation time of the motor 31 is less than 10,000 hours, the CPU 101 estimates a failure part to be the filter board 70, and estimates a defect cause to be a meltdown of a fuse. In a case where the motor 31 is not active, and an overvoltage abnormality is included in the usage history information, the CPU 101 estimates a failure part to be the filter board 70, and estimates a defect cause to be use with a power supply out of specification. In a case where the motor 31 is not active, and both an overvoltage abnormality and an overcurrent abnormality are included in the usage history information, the CPU 101 estimates a failure part to be the inverter board and the filter board 70, and estimates a defect cause to be use with a power supply out of specification. In a case where the motor 31 is not active, an abnormality is not included in the usage history information, and the number of operations of the trigger switch 59a is equal to or greater than 5,000 (a predetermined number of times for illustration), the CPU 101 estimates a failure part to be the trigger switch 59a, and estimates a defect cause to be the life span of the trigger switch 59a being exceeded. In a case where the motor 31 is not active, and an overcurrent abnormality and a high-temperature abnormality of the inverter circuit 65 are included in the usage history information, the CPU 101 estimates a failure part to be the inverter board, and estimates a defect cause to be an operation out of specification. In a case where an abnormality of the Hall IC 37 is included in the usage history information, the CPU 101 estimates a failure part to be the Hall IC board 38, and estimates a defect cause to be an abnormality of a motor portion. In a case where the motor 31 is active, and a high-temperature abnormality is included in the usage history information, the CPU 101 estimates a failure part not to be present, and estimates a defect cause to be an operation out of specification. In a case where the motor 31 is active, and an overvoltage abnormality is included in the usage history information, the CPU 101 estimates a failure part not to be present, and estimates a defect cause to be use with a power supply out of specification. In addition, it is also possible to diagnose the presence or absence of abnormalities of the diode bridge 67 and the capacitor C through a comparison between input and output voltages of the diode bridge 67 which is not shown in the drawing.

FIG. 12 is a diagram illustrating display of an initial screen of a failure diagnosis application which is displayed on the output device 104 by the diagnosis device 100. FIG. 12 is screen display immediately after the CPU 101 loads a diagnosis program from the memory 102, and starts up the diagnosis program. A “diagnosis start button” is a button on a screen for a user to start a diagnosis (to cause a process to transition to step S3 in FIG. 7). An “end button” is a button on a screen for terminating the failure diagnosis application. Besides, the screen display of the failure diagnosis application includes a portion that displays product information (information, such as a model name or a manufacturing number, for identifying the electric tool 1) of the electric tool 1 serving as the target which diagnosis is performed, a portion that displays a diagnosis result together with a recommended replacement part, and a portion that displays a usage history together with a defect cause.

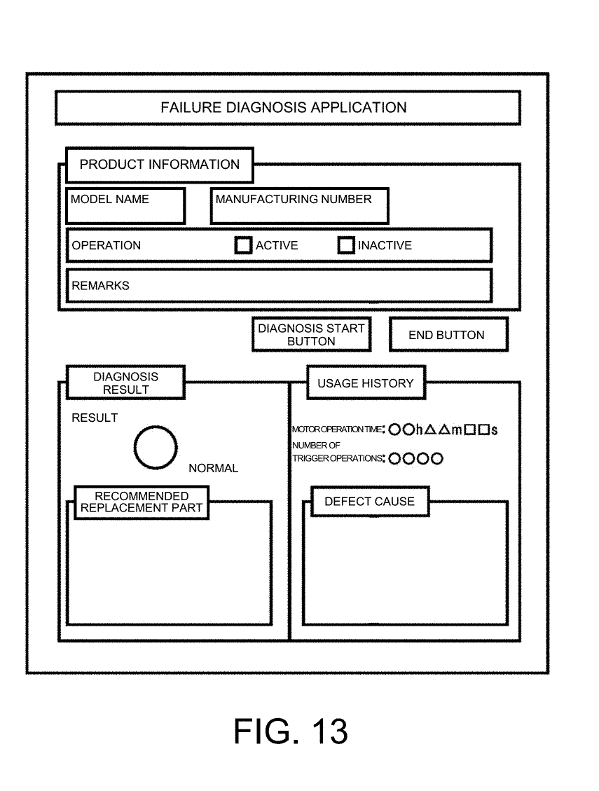

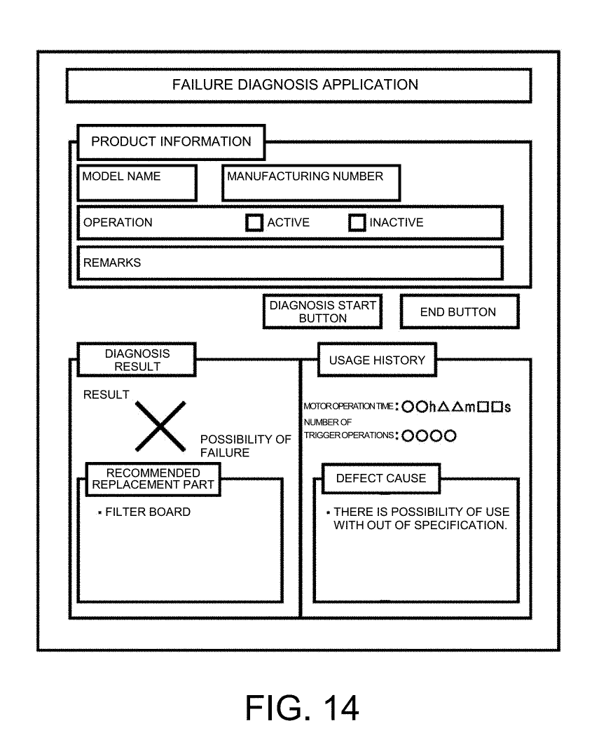

FIG. 13 is a diagram illustrating display in a case where a diagnosis result in the failure diagnosis application is normal. In a case where a diagnosis result is normal, display indicating that the diagnosis result is normal, and display of the cumulative operation time of the motor 31 and the number of times of accumulated operations of the trigger switch 59a as a usage history are performed. FIG. 14 is a diagram illustrating display in a case where a diagnosis result in the application is abnormal. In a case where a diagnosis result is abnormal, display indicating that the diagnosis result is abnormal, display of a recommended replacement part, and display of a usage history and a defect cause are performed.

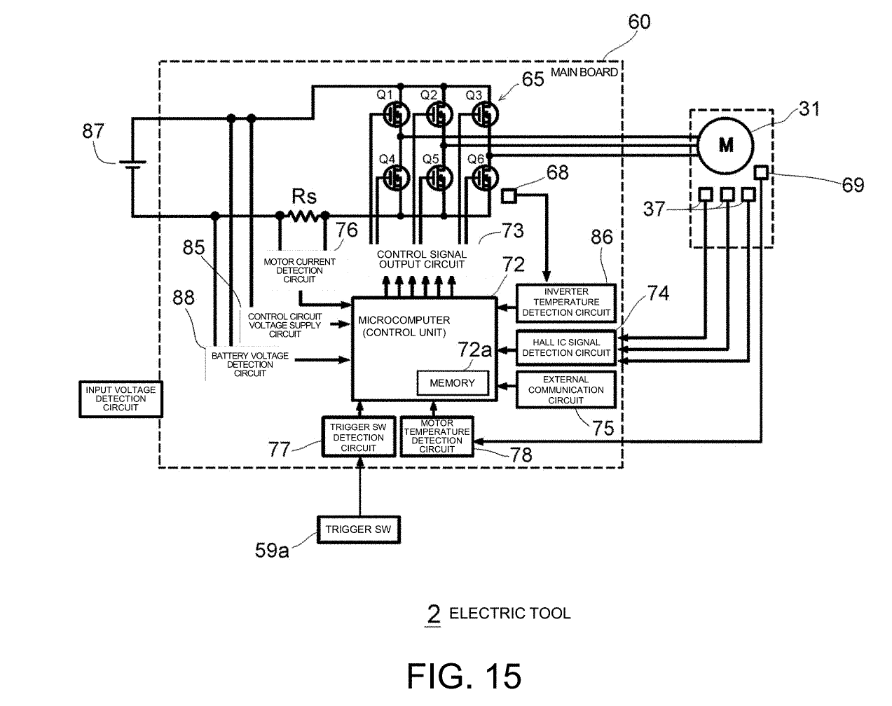

FIG. 15 is a circuit block diagram of a DC driving electric tool 2 in Embodiment 1. The electric tool 2 shown in FIG. 15 is different from the electric tool 1 shown in FIG. 1, in that the AC power supply 66 is replaced by a battery 87, the filter board 70, the diode bridge 67, and the capacitor C are not present, and the input voltage detection circuit 83 and the rectification voltage detection circuit 84 are replaced by a battery voltage detection circuit 88, and both are coincident with each other in other points. A battery driving (cordless type) electric tool such as the electric tool 2 can also be diagnosed by the diagnosis device 100, similarly to an AC driving (corded type) electric tool such as the electric tool 1.

According to the present embodiment, the following effects can be exhibited.

(1) Since a failure part of an electric tool is estimated on the basis of usage history information of the electric tool without being limited to the determination of the presence or absence of a failure of an electric tool as in the related art, and information indicating the failure part is reported, it is possible to easily identify the failure part of the electric tool. Particularly, since an electric tool using a brushless motor as a driving source has a large number of parts of an electronic circuit and around the circuit, there is a problem in that a failure part is not likely to be found during a failure, and that the time and cost required for repair become excessive due to even replacement or the like of a part which is not out of order. However, according to the present embodiment, it is possible to suitably suppress such a problem.

(2) Since the diagnosis device 100 may be a general-purpose computer, and is not required to prepare dedicated hardware for a failure diagnosis, the introduction of the failure diagnosis system is facilitated and low-priced.

(3) Since usage history information of an electric tool and a diagnosis result (failure estimation part or defect cause) based thereon are transmitted and accumulated from a plurality of diagnosis device 100 to the server 200, the tendency of failure occurrence according to the type or model of electric tool is analyzed on the basis of the accumulated information, and thus it is possible to acquire information useful to further improvement or product development.

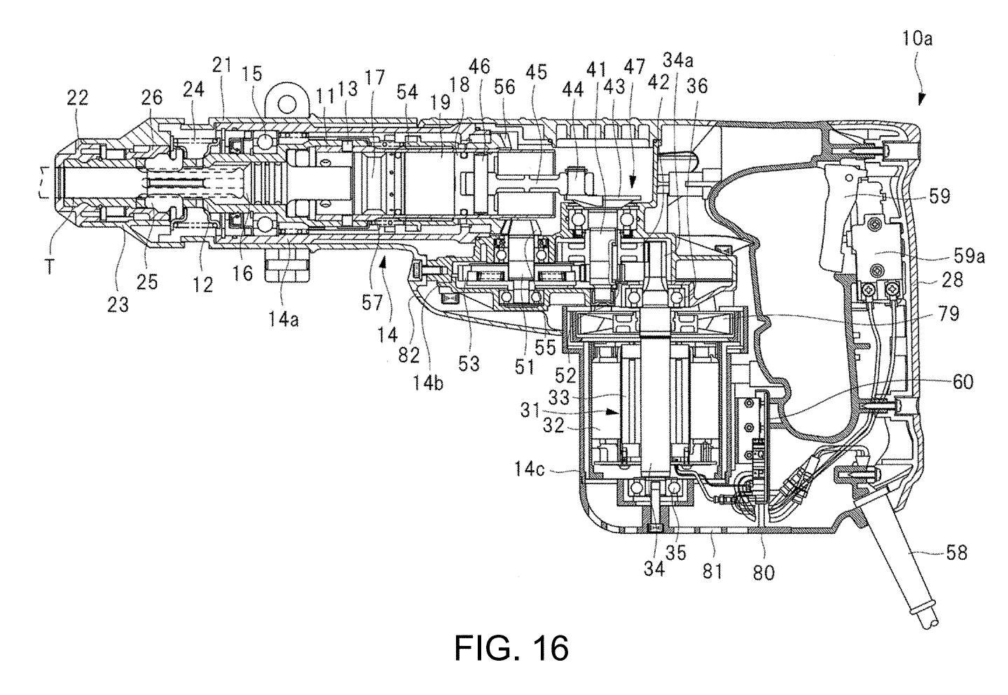

FIG. 16 is a cross-sectional side view of a working machine 10a which is an example of the AC driving electric tool 1. In the failure diagnosis system of the present embodiment, the type of electric tool is not particularly limited, but herein, a specific configuration of the working machine 10a will be described as an example with reference to FIG. 16. The working machine 10a shown in FIG. 16 is also referred to as a hammer drill, and has a tool T attached to and detached from the working machine 10a. The working machine 10a can apply a rotational force and a striking force to the tool T. The working machine 10a can perform chipping work, boring work, and fracturing work, using concrete, stone or the like as an object. The working machine 10a can be set by switching between a striking mode in which a striking force is applied to the tool T and a rotational striking mode in which a striking force and a rotational force are applied to the tool T.

The working machine 10a includes a housing 14, and the housing 14 includes a front case 21, a motor housing 14c fixed to the front case 21, an intermediate case 80 fixed to the front case 21 and the motor housing 14c, and a handle 28 attached to the intermediate case 80. A cylinder 11 is received within the front case 21, and a cylindrical tool holder 12 is fixed to the tip portion of this cylinder 11 by a pin 13. The tool holder 12 is supported by a cylinder housing 14a through a bearing 15, and the cylinder 11 and the tool holder 12 are rotatably mounted within the cylinder housing 14a. In a case where the tool T is attached to the tool holder 12, the rotational force of the cylinder 11 is transmitted to the tool T.

A hammer member 16 is axially reciprocatably incorporated within the tool holder 12, and a portion of the hammer member 16 is disposed within the cylinder 11. A striker 17 for applying a striking force to the hammer member 16 is axially reciprocatably disposed within the cylinder 11. In addition, a piston 18 is axially reciprocatably disposed within the cylinder 11. An air chamber 19 is provided between the striker 17 and the piston 18. The cylinder 11 has a ventilation hole and an exhaust hole which are connected to the air chamber 19.

A tip cap 22 made of rubber is attached to the tip of the tool holder 12. A removable sleeve 23 is axially reciprocatably mounted outside the tip cap 22, and a spring force in a direction away from the cylinder housing 14a, that is, in a forward direction is biased to the removable sleeve 23 by a coil spring 24. An engagement roller which is engaged with a groove provided in the tool T, that is, an engagement member 25 is radially movably mounted to the tool holder 12. The removable sleeve 23 is provided with a fastening ring 26.

In a case where the fastening ring 26 protrudes the engagement member 25 radially inward, the tool T is held by the tool holder 12. On the other hand, in a case where the removable sleeve 23 is backward moved against a spring force, the engagement of the fastening ring 26 with the engagement member 25 is released. In a case where the tool T is pulled on the basis of this state, the engagement member 25 is retreated radially outward, and thus the tool T can be detached therefrom. In addition, in a case where the tool T is inserted into the tip portion of the tool holder 12 on the basis of a state where the removable sleeve 23 is backward moved, and the tool holder 12 is forward moved by a spring force, the tool T is mounted to the tool holder 12 and is held by the engagement member 25.

A gear housing 14b is provided on the rear end of the cylinder housing 14a, and this gear housing 14b is provided with the motor housing 14c. The motor housing 14c faces a direction perpendicular to the cylinder housing 14a, and the housing 14 of the working machine 10a is formed by the cylinder housing 14a, the gear housing 14b, and the motor housing 14c.

The motor 31 is received within the motor housing 14c. The motor 31 is a brushless motor, and includes a cylindrical stator 32 having a coil wound therearound and a rotor 33 which is incorporated into the stator 32. An output shaft 34 is attached to the rotor 33, and the output shaft 34 is rotated about a shaft line in a direction perpendicular to the reciprocating direction (front-back direction) of the cylinder 11. The output shaft 34 is rotatably supported by bearings 35 and 36. Further, a cooling fan 79 rotating integrally together with the output shaft 34 is provided. In addition, the main board 60 is received within the motor housing 14c to the lateral side of the motor 31. The main board 60 is received so that its longitudinal direction becomes approximately parallel to a direction (vertical direction) in which the output shaft 34 extends. Meanwhile, as described above, the connector 64 may be extracted so as to face outside from the housing 14. In this case, it is preferable that the connector is provided in the vicinity (for example, a portion of the motor housing 14c which is provided with a suction hole 81) of the main board 60.

In order to convert the rotational force of the output shaft 34 of the motor 31 into the reciprocating operation force of the piston 18, a crank shaft 41 is rotatably mounted in the gear housing 14b. The crank shaft 41 is disposed on the tool holder side so as to be parallel to the output shaft 34, and a large-diameter pinion gear 42 provided on the crank shaft 41 is engaged with a gear portion 34a provided on the tip portion of the output shaft 34. An eccentric member 43 having a function as a crank weight is attached to the tip portion of the crank shaft 41.

A crank pin 44 is attached to the eccentric member 43 at a position which is eccentric from the rotational center of the crank shaft 41. A first end of a connecting rod 45 is rotatably fitted to the crank pin 44. A second end of the connecting rod 45 is swingably fitted to a piston pin 46 attached to the piston 18. The rotational force of the crank shaft 41 is converted into the reciprocating operation force of the piston 18 by a motion conversion mechanism 47 having the eccentric member 43 and the connecting rod 45.

A rotational force transmission shaft 51 is rotatably provided within the gear housing 14b. The rotational force transmission shaft 51 is an element that transfers the rotational force of the output shaft 34 to the cylinder 11, and the rotational force transmission shaft 51 is provided with a pinion gear 53. The pinion gear 53 is engaged with a pinion gear 52 provided on the crank shaft 41.

The motion conversion mechanism 47 transfers the rotational force of the output shaft 34 to the rotational force transmission shaft 51. A driven sleeve 54 is axially movably fitted to the outside of the cylinder 11, and this driven sleeve 54 is provided with a bevel gear 56. The bevel gear 56 is engaged with a bevel gear 55 provided on the rotational force transmission shaft 51. A key member which is not shown in the drawing is provided between the driven sleeve 54 and the cylinder 11. In order to bias a spring force in a backward direction with respect to the driven sleeve 54, a coil spring 57 is mounted within the cylinder housing 14a.

Further, the intermediate case 80 is provided with the suction hole 81. In a case where the cooling fan 79 rotates, air outside of the housing 14 is suctioned into the housing 14 through the suction hole 81 and thus draws heat of a heat generating portion within the housing 14. The front case 21 is provided with an exhaust hole 82, and the air suctioned into the housing 14 is discharged from the exhaust hole 82 to the outside of the housing 14.

In addition, an operating mode switching lever which is not shown in the drawing is provided in the housing 14. An operator can switch the striking mode and the rotational striking mode by operating the operating mode switching lever. In a case where the striking mode is selected, the working machine 10a applies a striking force to the tool T, and does not apply a rotational force. In a case where the rotational striking mode is selected, the working machine 10a applies a striking force and a rotational force to the tool T.

In a case where the rotational striking mode is selected, the driven sleeve 54 is backward moved to a position at which the bevel gear 56 on the driven side is engaged with the bevel gear 55 on the driving side, and the driven sleeve 54 is engaged with the cylinder 11 by the key member. This leads to a state where the rotational force of the output shaft 34 can be transferred to the cylinder 11. On the other hand, in a case where the striking mode is selected, the driven sleeve 54 is forward moved, and the engagement of the driven sleeve 54 with the cylinder 11 is released. Therefore, a rotational force is not transmitted to the cylinder 11.

The motor 31 is driven by a current being supplied from the AC power supply 66. A feed cable 58 is attached to the handle 28. An electrical outlet which is not shown in the drawing is provided on the tip of the feed cable 58, and the electrical outlet is connected to the AC power supply 66. A trigger 59 for switching the rotation and stop of the motor 31 is provided. The stop of the motor 31 means that the motor 31 is in an inactive state. The rotation of the motor 31 means that the motor 31 is in an active state. The stop of the motor 31 includes the meanings that the rotating motor 31 is stopped, and the motor 31 continues to be stopped. The trigger 59 is provided in the handle 28, and the turn-on and turn-off of the trigger switch 59a are switched by the trigger 59 being operated.

The housing 14 is provided with a rotation speed setting dial (not shown) for an operator to set the rotation speed of the motor 31. An operator operates the rotation speed setting dial to set the rotation speed of the motor 31. The rotation speed which is set by the operation of the rotation speed setting dial is a target rotation speed used in a case where a load of the motor 31 is in existence. A load of the motor 31 being in existence means that an object is being processed in the tool T. The housing 14 is provided with a display portion which is not shown in the drawing. The display portion includes a display that displays a set target rotation speed, and an LED lamp that displays a temperature within the housing 14 and the stop of the motor 31.

Next, an example of use of the working machine 10a will be described. In a case where the striking mode is selected, and the trigger 59 is operated, the output shaft 34 of the motor 31 rotates, and the rotational force of the output shaft 34 is converted into the reciprocating force of the piston 18 by the motion conversion mechanism 47. In a case where the tool T is pressed against an object during the rotation of the output shaft 34 of the motor 31, the striker 17 blocks the exhaust hole. In a case where the piston 18 moves toward the striker 17 in a state where the exhaust hole is blocked, the pressure of the air chamber 19 rises. In a case where the pressure of the air chamber 19 rises, the striker 17 strikes the hammer member 16, and the striking force is transmitted to the tool T.

On the other hand, in a case where the tool T is away from an object during the rotation of the output shaft 34 of the motor 31, the striker 17 is stopped at a standby position away from the piston 18 under its own weight. In a case where the striker 17 is stopped at the standby position, the exhaust hole is opened. Even when the piston 18 moves toward the striker 17 in a state where the exhaust hole is opened, the pressure of the air chamber 19 does not rise, and the tool T is not struck.

Meanwhile, in a case where the striking mode is selected, the driven sleeve 54 is forward moved, and the engagement of the driven sleeve 54 with the cylinder 11 is released. Therefore, the rotational force of the output shaft 34 is not transmitted to the cylinder 11, regardless of whether the tool T is pressed against an object.

On the other hand, in a case where the rotational striking mode is selected, the output shaft 34 of the motor 31 rotates, and the tool T is pressed against an object, the striker 17 strikes the hammer member 16 similarly to the case where the striking mode is selected, and the striking force is transmitted to the tool T.

Further, in a case where the rotational striking mode is selected, the driven sleeve 54 is backward moved, and the driven sleeve 54 and the cylinder 11 are engaged with each other. Therefore, the rotational force of the output shaft 34 is transmitted to the cylinder 11. That is, a striking force and a rotational force are transmitted to the tool T. Meanwhile, in a case where the rotational striking mode is selected, and the tool T is away from an object, the tool T is not struck similarly to the case where the striking mode is selected.

In addition, in a case where the cooling fan 79 rotates together with the output shaft 34 of the motor 31, air outside of the housing 14 is absorbed into the housing 14 through the suction hole 81. The air absorbed into the housing 14 draws heat of the motor 31 and heat of the inverter circuit 65, and then is discharged from the exhaust hole 82 to the outside of the housing 14. Therefore, the motor 31 and the inverter circuit 65 are cooled.

### Embodiment 2

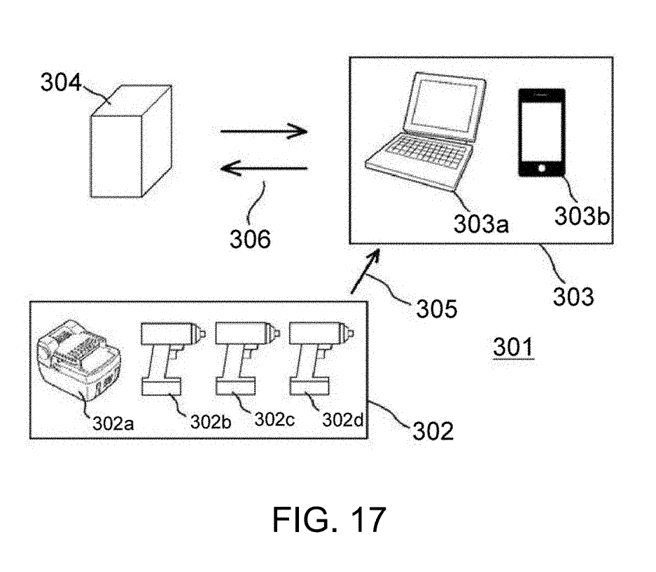

Hereinafter, Embodiment 2 of the present invention will be described with reference to FIG. 17 and the subsequent drawings. As shown in FIG. 17, a management system 301 is mainly constituted by an instrument 302 such as a battery pack or an electric tool having unique identification information, such as a unique ID (unique ID or product ID), for identifying a product, an intermediate device 303 such as a personal computer or a tablet terminal, installed in a sales shop, a repair center or the like, which reads in and displays information of the instrument 302 or information of a management device (server) 304 by being connected to the instrument 302 through wireless or wired 305, and a management device 304 that stores information or the like of the instrument 302 by being connected to the intermediate device 303 through a network 306 such as the Internet or a telephone line.

The instrument 302 includes a battery pack 302a and electric tools 302b to 302d. Each instrument 302 includes a control unit and a first storage unit 321 therein, and stores unique information of the instrument 302 in the first storage unit 321. The unique information includes a unique ID for identifying the instrument 302 or usage history information of the instrument 302. In the unique ID, for example, in a state where the battery pack 302a is set to 0001, the electric tool 302b is set to 1234, the electric tool 302c is set to 1235, and the electric tool 302d is set to 1236, a different unique ID for each model is allocated, and is stored in the first storage unit 321 which is built-in. The usage history information is information such as, for example, the total number of times of operation of a trigger (number of operations), the total driving time (operation time) of a motor, the number of times of overcurrent state, the number of times of high temperature, or error information (number of errors) in a case where the instrument 302 is the electric tools 302b to 302d, and includes information such as the number of times of connection to an electric tool, the number of times of charging, or the number of times of overcharging or overdischarging in a case where the instrument 302 is the battery pack 302a. Alternatively, in a case where the instrument 302 is a charger, the information can also be set to information such as the total number of times of charging, the number of times of overcharging, or the number of times of charging of a high-temperature battery pack. Whenever the battery pack 302a or each of the electric tools 302b to 302d is used, its use information (such as a motor driving time) is overwritten in the first storage unit 321, and the total use information thus far is updated and is stored in the first storage unit 321. This unique information is equivalent to first information.

The intermediate device 303 is constituted by a personal computer 303a, a tablet 303b, a smartphone, and the like. The intermediate device 303 is installed in a sales shop, a business center, a repair center, or the like. The intermediate device 303 is connected to the instrument 302 in a wireless or wired manner. The instrument 302 is provided with a control unit and a communication unit (wireless or wired), and the communication unit of the instrument and the communication unit of the intermediate device 303 are configured to be capable of communicating with each other. The intermediate device 303 has an application for information management, and unique information stored in the first storage unit 321 of the instrument 302 is transmitted to the intermediate device 303 by starting up the application to start communication. A specific transmission method will be described later. In addition, the intermediate device 303 is configured to read in unique information stored in the instrument 302, and to be capable of displaying necessary unique information on a screen, and automatically transmits the unique information which is read into the management device 304. Since the intermediate device 303 is installed at each shop (such as a sales shop, a repair center, or a business center), the unique information of the specific instrument 302 (for example, electric tool 302b) can be confirmed (displayed) at all the shops.

The management device 304 (server) includes a control unit and a second storage unit 341, and is connected to the intermediate device 303 through the network 306. The management device 304 is installed at only one place (for example, building interior of a maker) without being installed for each shop. Data (storage information of the second storage unit 341 of the management device 304) can be collectively managed on the maker side by installing the management device within the maker, and it becomes easy to analyze the information. The second storage unit 341 stores diagnosis information such as a diagnosis date, a diagnosis result, or the past repair part of each instrument 302 where the instrument 302 is diagnosed by the intermediate device 303, and client information of a client who possesses each instrument 302, in addition to the unique information of the instrument 302 which is read in from the first storage unit 321 through the intermediate device 303. These pieces of information are equivalent to second information. The diagnosis information is transmitted from the intermediate device 303 to the management device 304 when the instrument 302 is diagnosed (when the instrument 302 is connected to the intermediate device 303 and an application is started up), and is stored in the second storage unit 341 of the management device 304. In addition, the client information may be input by an operator (for example, serviceman) on the maker side or a user by providing an input part onto a screen of an application of the intermediate device 303, or information of the instrument 302 may be registered by previously performing user registration with the user side on an application of a smartphone or the like or a homepage of a maker. When the instrument 302 is connected to the intermediate device 303 and is diagnosed, the unique ID of the instrument 302 which is read into the intermediate device 303 is inquired of the management device 304, and thus it is possible to find out an owner of the instrument 302 to be diagnosed. The second storage unit 341 of the management device 304 also stores a unique ID (management-side unique ID) according to the unique ID (instrument-side unique ID) of each instrument 302. Here, although a detailed description will be given later, the management-side unique ID is stored in the second storage unit 341 by registering the instrument 302 from the intermediate device 303 in a case where the instrument has been diagnosed in the past. Meanwhile, the client information includes production information (such as a manufacturing date or a manufacturing place) of the instrument 302, a purchaser name, a purchase date and a sales shop relating to purchase of the instrument 302, a manager name, a repair shop name, and a repair history of the instrument 302, and the like. This client information is not stored in the first storage unit 321 on the instrument 302 side, and thus it is possible to effectively use the first storage unit 321 on the instrument 302 side. Thereby, it is possible to store much unique information (such as an operation time) capable of being stored only in the instrument 302.

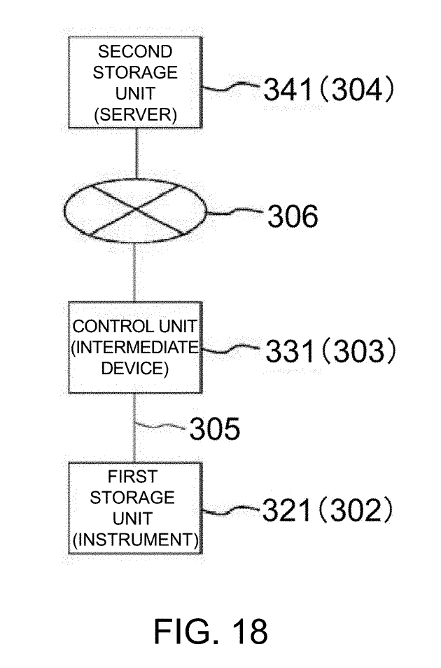

Next, reference will be made to FIG. 18 to describe connection between the instrument 302 (first storage unit 321) and the management device 304 (second storage unit 341) in a case where the intermediate device 303 is installed at only one place. The intermediate device 303 is installed at, for example, one place of a sales shop, and the management device 304 is also installed at only one place of a maker. The instrument 302 (for example, electric tool 302b) has the first storage unit 321 (first control unit) built-in. In addition, the management device 304 has the second storage unit 341 (second control unit) built-in. In a case where the instrument 302 is connected to the intermediate device 303 and an application for information management is started up, a control unit 331 of the intermediate device 303 read in unique information from the first storage unit 321 through the communication unit 305. The control unit 331 overwrites, updates, and stores information which is read into the second storage unit 341 of the management device 304 through the network 306. In a case of FIG. 18, since the instrument 302 (first storage unit 321), the intermediate device 303 (control unit 331), and the management device 304 (second storage unit 341) have one-to-one relations with each other, information of the first storage unit 321 is stored in the second storage unit 341 through the control unit 331 and the network 306. The control unit 331 can read out information stored in the second storage unit 341, and display the read-out information on a screen. In addition, information stored in the first storage unit 321 can also be displayed on a screen.

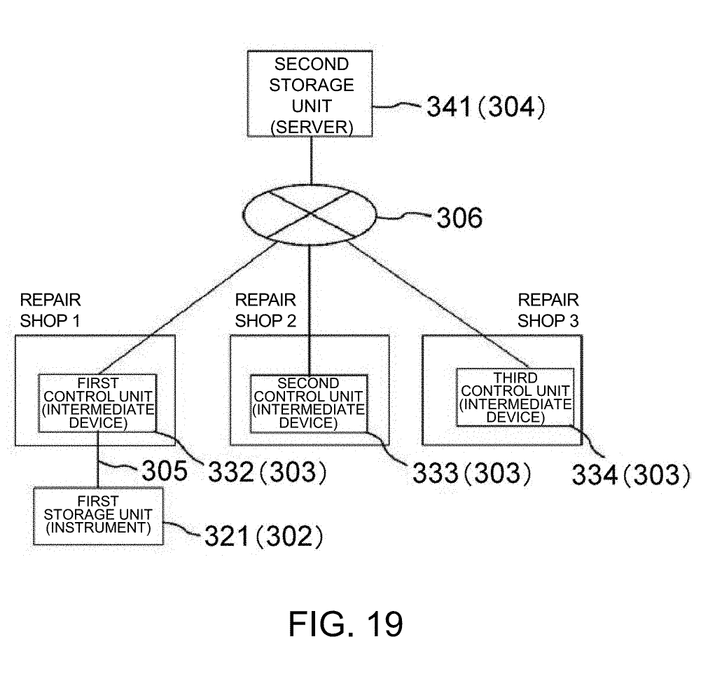

Next, reference will be made to FIG. 19 to describe connection between the instrument 302 (first storage unit 321) and the management device 304 (the second storage unit 341) in a case where the intermediate device 303 is installed at three places. The intermediate device 303 is installed at, for example, each of three repair shops different from each other. On the other hand, the management device 304 is installed at only one place of a maker without being installed at each repair shop. The respective intermediate devices 303 (such as personal computers) are provided with control units 332 to 334.

In a case where the instrument 302 is connected to the intermediate device 303 of a repair shop 1 and an application for information management is started up, the control unit 332 of the intermediate device 303 reads in unique information from the first storage unit 321 of the instrument 302 through the communication unit 305, and overwrites, updates, and stores the information in the second storage unit 341 of the management device 304 through the network 306. Control for storing the unique information of the instrument 302 in the second storage unit 341 of the management device 304 is the same as that in the case of FIG. 2. In a case where the unique information of the instrument 302 (for example, electric tool 302b) is desired to be confirmed in the repair shop 1, the information stored in the management device 304 can be read in by an application for information management and be displayed on the screen of the intermediate device 303.

On the other hand, in a repair shop 2 and a repair shop 3 which are separate from the repair shop 1, there may be a case where information of the same instrument 302 (electric tool 302b) diagnosed in the repair shop 1 is desired to be confirmed. In this case, information of electric tool 302b can be confirmed without the electric tool 302b being brought into repair shops other than the repair shop 1. The intermediate device 303 installed at repair shops other than the repair shop 1 has also a second control unit 333, a third control unit 334, and an application for information management built-in. For example, in a case where the application is started up in the second control unit 333 to start its operation, the second control unit 333 has access to the second storage unit 341 of the management device 304, and the information of the electric tool 302b desired to be confirmed can be read in and be displayed on a screen. That is, since the management device 304 is installed so as to be capable of being accessed from all the shops, it is possible to confirm information of the brought-in instrument 302 and to share the information, even from shops other than the repair shop 1 into which the instrument 302 is brought.

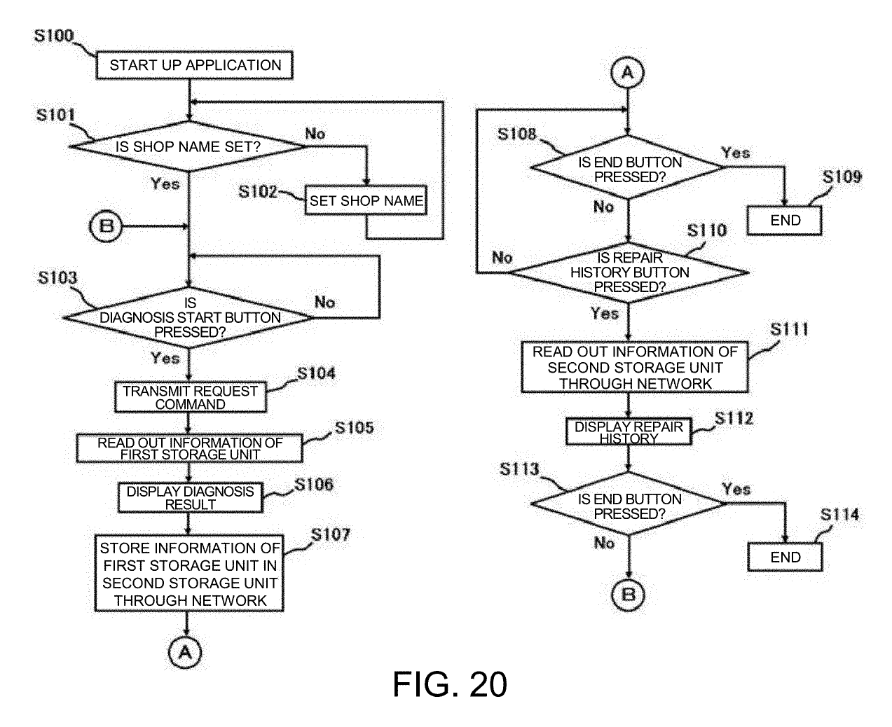

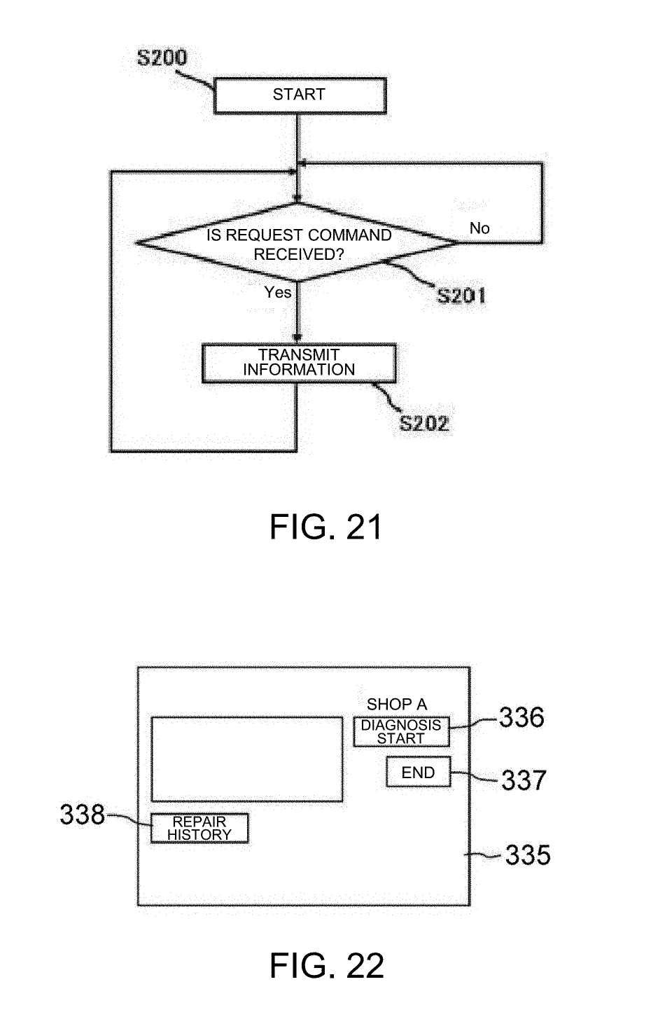

Next, a method of storing unique information stored in the first storage unit 321 of the electric tool 302b in the second storage unit 341 of the management device 304 will be described with reference to FIGS. 20 to 25. Here, in FIG. 19, a description will be given of a case where the information of the electric tool 302b as the instrument 302 is stored in the management device 3 at the repair shop 1 (shop A). FIG. 20 is a control flowchart of the control unit 332 of the intermediate device 303, and FIG. 21 is a control flowchart of the control unit of the electric tool 302b. FIGS. 22 to 25 are display screens 335 serving as display portions of the intermediate device 303, and show examples of display details to be displayed.

Initially, an operator of the shop A starts up an application for information management stored in the intermediate device 303 in a state where the electric tool 302b and the intermediate device 303 (control unit 331) are connected to each other (step S100). A screen for confirming at which shop storage work which is being currently performed is performed is displayed on the display screen 335 of the intermediate device 303. In a case where a shop name is not registered (No in step S101), a list of shop names is displayed, whereby a shop name is selected among them, and a determination button which is not shown is pressed to make a setting (step S102). On the other hand, in a case where a shop name is registered (Yes in step S101), as shown in FIG. 22, a shop name (for example, shop A) under current work is displayed on the display screen 335.

After a shop name is set, the control unit 332 determines whether a diagnosis start button 336 on the display screen 335 is pressed (step S103). In a case where the diagnosis start button 336 is not pressed (No in step S103), standing by until the diagnosis start button 336 is pressed. In a case where the diagnosis start button 336 is pressed (Yes in step S103), a request command signal for requesting reading-out of unique information stored in the first storage unit 321 is transmitted to the control unit of the electric tool 302b (step S104).

Here, control for the control unit of the electric tool 302b to read the unique information will be described with reference to FIG. 21. The control unit (for example, microcomputer) of the electric tool 302b is started up by power being supplied from the intermediate device 303 through connection to the intermediate device 303, and starts control of FIG. 21 (step S200). Meanwhile, in a configuration in which the electric tool 302b is driven by a battery pack, the electric tool 302b can be connected to the intermediate device 303 in a state where the battery pack is connected. In this case, the control unit of the electric tool 302b can be started up by power being supplied from the battery pack or the intermediate device 303, and power consumption of the battery pack can be reduced when the power-supply line of the battery pack is cut off by a cutoff signal from the intermediate device 303 or the control unit in a case where power is supplied from the intermediate device 303. In addition, in a case of connection to the intermediate device 303 in a state where the battery pack is removed, or a case of the electric tool driven connected to the commercial power supply, the control unit is supplied with power from the intermediate device 303.

The control unit determines whether a request command signal has been received from the intermediate device 303 in step S104 of FIG. 20 (step S201). In a case where the request command signal is received (Yes in step S201), the control unit transmits the unique information (for example, unique ID or usage history information) of the electric tool 302b stored in the first storage unit 321 to the intermediate device 303 (step S202). Thereafter, the control unit terminates this control in a case where the supply of power to the control unit is cut off such as a case where the electric tool 302d is removed from the intermediate device 303, or a case where the supply of power from the intermediate device 303 is turned off.

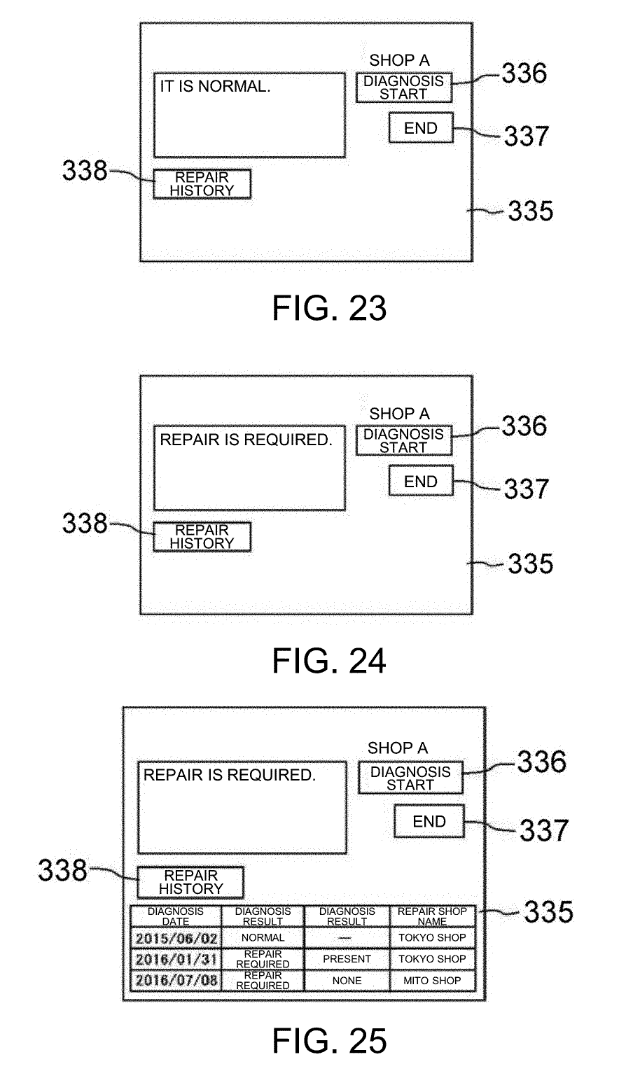

Returning back to the control unit 332, the control unit 332 of the intermediate device 303 reads out the unique information of the electric tool 302b from the first storage unit 321 of the electric tool 302b in step S202 (step S105), and displays the information of the electric tool 302b such as the unique information on the display screen 335 (step S106). Meanwhile, in step S106, a diagnosis result rather than the unique information is displayed. This is because a used application is for diagnosis. All the pieces of information or some pieces of information stored in the first storage unit 321 can be displayed, and an application of a specification according to an operator's request may be used. The diagnosis result is a result obtained by comparing the read-out unique information with the information stored in the control unit 332. For example, in a case where the total operation time of the motor exceeds a predetermined value, repair (maintenance) may be prompted. In a case where a result of a diagnosis based on the information stored in the first storage unit 321 indicates that the electric tool 302b is normal, it is displayed that the electric tool is normal as shown in FIG. 23. On the other hand, in a case where the electric tool is abnormal, it is displayed that repair is required as shown in FIG. 24.

Thereafter, the control unit 332 causes the second storage unit 341 of the management device 304 to store the unique information of the electric tool 302b read out from the first storage unit 321 through the network 306 (step S107). The second storage unit 341 of the management device 304 stores the information of not only the electric tool 302b but only the instrument 302 diagnosed (managed) at all the shops. Meanwhile, after the unique information read out from the first storage unit 321 is stored in the second storage unit 341, the information stored in the first storage unit 321 can also be deleted. In this case, even in a case where the storage capacity of the first storage unit 321 is small, the storage capacity can be effectively used. During reconnection to the management device 304, the amount of update from previously stored information may be stored in the second storage unit 341. In addition, the information may be overwritten without being deleted.

Up-to-date information is overwritten and stored in the unique information stored in the second storage unit 341. Meanwhile, the control unit 332 retrieves the unique ID (for example, ID1234) of the electric tool 302b from information (unique ID information of each instrument) stored in the second storage unit 341 of the management device 304, and reads out the information in a case where the unique ID is identical, thereby allowing the past information of an instrument 302 which is being diagnosed to be reliably retrieve. The control unit 332 then determines whether an end button 337 on the display screen 335 is pressed (step S108), terminates an information management process in a case where the end button is pressed (Yes in step S108), and terminates an application (step S109). Meanwhile, in a case where the application of the intermediate device 303 is terminated, control on the instrument 302 side in FIG. 21 is also terminated.

On the other hand, in a case where the end button 337 is not pressed (No in step S108), it is determined whether a repair history button 338 on the display screen 335 is pressed (step S110). In a case where the repair history button 338 is not pressed (No in step S110), the process returns to step S108, and standing by until the end button 337 or the repair history button 338 is pressed. In a case where the repair history button 338 is pressed (Yes in step S110), information relating to a repair history of the electric tool 302b is read out from the second storage unit 341 of the management device 304 (server) through the network 306 (step S111), and the repair history is displayed on the display screen 335 as shown in FIG. 25 (step S112). FIG. 25 is an example of the repair history, and displays a diagnosis date, a diagnosis result, a repair history, and a repair shop name. The diagnosis date is a date (diagnosis date) on which the unique information of the electric tool 302b is stored in the management device 304 using this application. The diagnosis result is a result determined on the basis of information stored in the first storage unit 321 of the electric tool 302b. The repair history indicates whether repair has been performed in a case where repair is required. The repair shop name is a repair shop having diagnosed the electric tool 302b using this application. Meanwhile, the diagnosis history displayed on the display screen 335 may be changed by an operator without being limited thereto.

After the repair history is displayed, it is determined whether the end button 337 is pressed again (step S113), and a diagnosis is terminated (application is terminated) in a case where the end button 337 is pressed (step S114). In a case where the end button 337 is not pressed, the process returns to step S103 followed by entering a standby state. In the present embodiment, an application for diagnosis is used as the application for information management. Therefore, the diagnosis result is displayed in step S106, and the repair history is displayed in step S112. However, in a case where an operation history application is used rather than the application for diagnosis, it is also possible to display operation information of the connected instrument 302. That is, it is possible to display various types of information in accordance with applications to be used. On the other hand, all pieces of information are stored in the management device 304 regardless of applications to be used.

Incidentally, in the present embodiment, the management device 304 is not installed at each shop, but is installed at only one shop so as to be accessible from each shop. The intermediate device 303 is installed at each shop. Therefore, in a case where application for information management is put into the intermediate device 303, information of the instrument 302 diagnosed in the past can be individually confirmed at each shop just by access the management device 304 from each shop through the network 306. From a repair shop 2 (shop B), for example, other than the repair shop 1 (shop A), information relating to the electric tool 302b diagnosed at the repair shop 1 can be displayed on the display screen 335 of the intermediate device 303 of the repair shop 2 and be confirmed as shown in FIGS. 22 to 25.

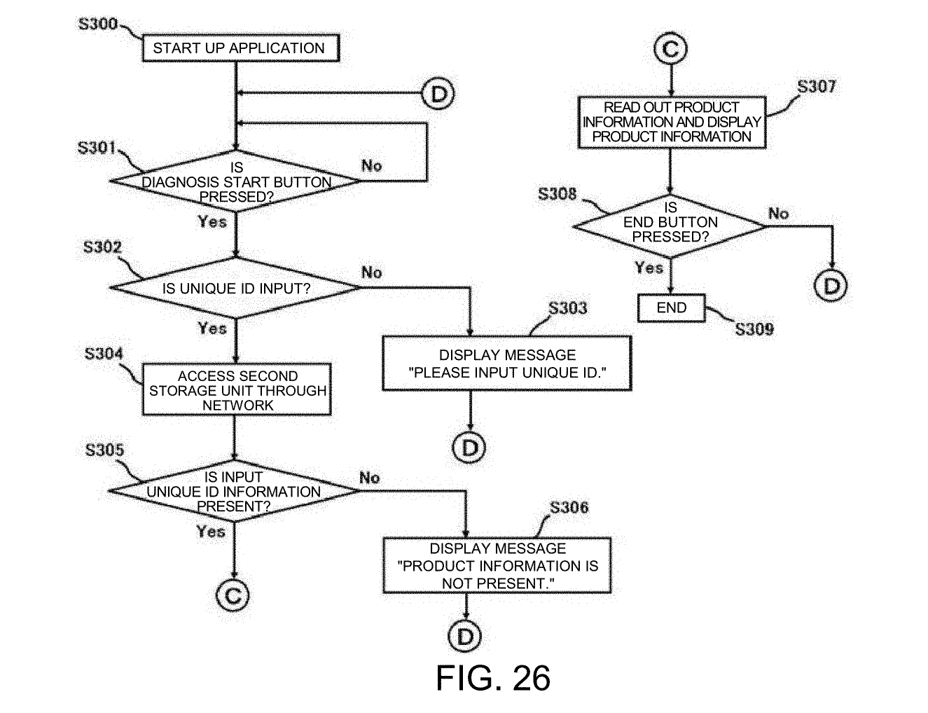

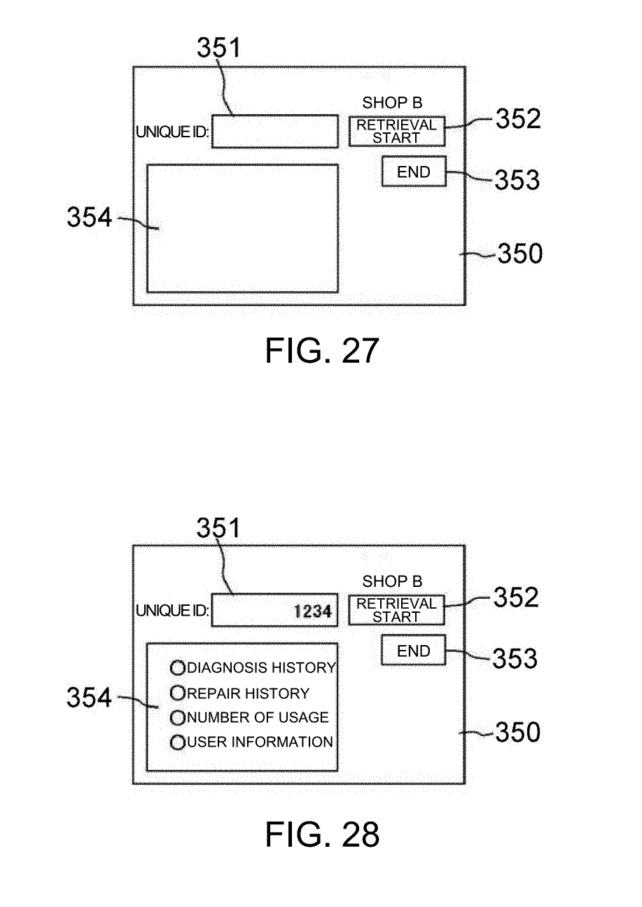

Here, a method of diagnosing the electric tool 302b at the repair shop 1 (shop A), and then confirming the information of the electric tool 302b at the repair shop 2 (shop B) will be described with reference to FIGS. 26 to 28. Control in FIG. 26 is executed by the control unit (the second control unit 333 of the repair shop 2 in FIG. 19 in the present embodiment) built into the intermediate device 303. Initially, an operator starts up an application of the intermediate device 303 (personal computer or tablet terminal) of the repair shop 2 (step S300). A screen shown in FIG. 27 is displayed on a display screen 350 of the intermediate device 303. The second control unit 333 determines whether a retrieval start button 352 displayed on the display screen 350 is pressed (step S301), and stands by until the button is pressed.

In a case where it is determined that the retrieval start button 352 is pressed (Yes in step S301), the second control unit 333 determines whether the unique ID of an instrument 302 desired to be retrieved is input to a unique ID input portion 351 (step S302). The input of a unique ID can be performed using a numeric keypad or the like which is provided on the intermediate device 2. In a case where the unique ID is not input (No in step S302), an error message, for example, “Please input the product ID.” is displayed on a display portion 354 of the display screen 350 (step S303), and the process returns to step S301.

On the other hand, in a case where “1234” indicating the unique ID, for example, the unique ID of the electric tool 302b is input to the unique ID input portion 351 (Yes in step S302), the second control unit 333 has access to the second storage unit 341 of the management device 304 (step S304), and retrieves whether the information of the electric tool 302b corresponding to the input unique ID is stored in the second storage unit 341 (step S305). Specifically, the unique ID of an instrument 302 diagnosed in the past and information relevant to the unique ID are stored in the second storage unit 341, and the second control unit retrieves whether a unique ID coincident with the input unique ID is stored.

In a case where a unique ID coincident with the input unique ID is not able to be retrieved (No in step S305), an error message, for example, “No product information” is displayed on the display portion 354 of the display screen 350 (step S306), and the process returns to step S301. On the other hand, in a case where an unique ID coincident with the input unique ID is present (Yes in step S305), the second control unit 333 reads out product information relevant to the unique ID from the second storage unit 341 of the management device 304 and displays the product information on the display portion 354. Examples of the product information capable of being displayed, for example, as shown in FIG. 28, include the past diagnosis history or repair history (for example, information shown in FIG. 25), the number of times of usage (such as the number of operations of a trigger of the electric tool 302b or the total driving time of a motor), or user information (such as an owner name, a purchase date, or a purchase shop name). Meanwhile, the display details can be changed in accordance with applications to be used. It is determined whether an end button 353 of the display screen 350 is pressed (step S308). The application is terminated in a case where the end button is pressed, the process returns to step S301 in a case where the end button is not pressed, and standing by until the end button is operated next. Such a process can also be performed at a repair shop 3 (shop C) in a case where the same application is put into the intermediate device 303.

According to the present embodiment, an operator or a user does not need to bring an instrument 302 desired to be diagnosed (information confirmation) into the repair shop 1 at which a diagnosis has been made in the past, and can confirm information of the instrument 302 at any repair shops other than the repair shop 1. Therefore, as compared with a case where the management device 304 is installed at each shop, it is possible to eliminate the complexity of information management. Further, since the second storage unit 341 of the management device 304 can obtain the information of each instrument 302 in real time, it is possible to obtain real-time information from any shops.

Further, only unique information of an instrument 302, for example, operation information such as the total driving time of a motor, which is required to be stored in the instrument 302 is stored in the first storage unit 321 of the instrument 302, and information (such as, for example, a purchase date of the instrument 302) having no problem with the operation management of the instrument 302 without being stored in the instrument 302 is stored not in the first storage unit 321, but in the second storage unit 341 of the management device 304, whereby it is possible to effectively utilize the storage capacity of the first storage unit 321. Therefore, it is not necessary that information of the first storage unit 321 is frequently stored and overwritten in the second storage unit 341 of the management device 304 to secure the storage capacity by deleting the information of the first storage unit 321. Therefore, as compared with a case where all pieces of information are stored in the first storage unit 321, it is possible to effectively utilize the storage capacity of the first storage unit 321, to reduce the size of the first storage unit 321 by storing only required minimum information (usage history such as operation information), and to suppress the cost and reduce the size of an instrument body. Meanwhile, in a case where it is not necessary to reduce the cost and size of the instrument body, all pieces of information may be stored by increasing the capacity of the first storage unit 321.

### Embodiment 3

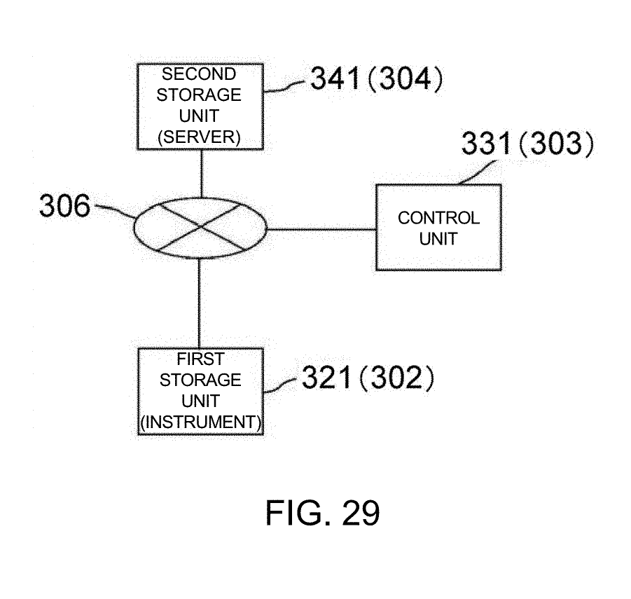

Next, Embodiment 3 will be described with reference to FIG. 29. FIG. 29 shows a configuration in which the instrument 302 is directly connected to the management device 304 without going through the intermediate device 303 (such as a personal computer or a tablet terminal). In this case, the application of the intermediate device 303 described in Embodiment 2 is put into the instrument 302. Further, the instrument 302 is provided with connection means for connection to the management device 304. The instrument 302 is provided with a display portion for displaying an operation button of the application or a diagnosis result. Similarly to Embodiment 2, a diagnosis method is executed along the control flows of FIGS. 20 and 21. Meanwhile, according to this configuration, in a case where the instrument 302 is connected to the network 306, information can be confirmed on the display portion of the instrument 302, and thus it is not necessary to provide the intermediate device 303.

Alternatively, only required minimum information may be managed in the management device 304 so as not to increase the storage capacity of the first storage unit 321 of the instrument 302. Although not shown in the instrument 302, an operating panel for changing a rotation speed or a driving mode is provided, and the operating panel is operated in a state of being connected to the management device 304, whereby management information may be reported to an operator. Since an instrument 302 is provided with its unique ID, the management device 304 can identify a connected instrument 302. A configuration may be used in which information according to the operation part or the number of times of operation of the operating panel, for example, the total driving time of a motor is selected in a case where a first button of the operating panel is pressed once, the information is read out from the first storage unit 321 to the second storage unit 341, the control unit of the management device 304 determines whether the total driving time reaches the limit driving time (threshold) of the identified instrument 302, a signal is output from the management device 304 to the instrument 302 in a case of reaching, and maintenance is prompted by turning on and off a display portion such as a light or a remaining battery power display portion provided in the instrument 302. In addition, in a case where the intermediate device 303 is provided, a screen as shown in FIG. 24 may be displayed on the display screen of the intermediate device 303. In this case, the intermediate device 303 just functions as a display portion.

In addition, a configuration may be used in which an application is put into the intermediate device 303, the instrument 302 is directly connected to the management device 304, and information stored in the first storage unit 321 of the instrument 302 and information stored in the second storage unit 341 of the management device 304 are read out to the intermediate device 303 through the network 306, to thereby make a diagnose similarly to Embodiment 2.

In addition, an application is not limited to diagnosis used, and in a case where an application according to an operator's or a user's request is prepared, the application can be adapted to a wide range of users.

Hereinbefore, while the present invention has been described by way of embodiments, it can be readily understood by those skilled in the art that respective components and respective treating processes of the embodiments may be variously modified and changed in the scope of the claims. Hereinafter, a modification example will be mentioned.

The electric tool may have a speed adjusting function based on conduction angle control of a switching element such as a triac, using a motor with a brush as a driving source. A result of diagnosis made by the diagnosis device 100 may be reported using a voice in place of screen display or in addition thereto.

### REFERENCE SIGNS LIST

1, 2 Electric tool
10a Working machine (hammer drill)
11 Cylinder
12 Tool holder
13 Pin
14 Housing
14a Cylinder housing
14b Gear housing
14c Motor housing
15 Bearing
16 Hammer member
17 Striker
18 Piston
19 Air chamber
21 Front case
22 Tip cap
23 Removable sleeve
24 Coil spring
25 Engagement member
26 Fastening ring
28 Handle
31 Motor (brushless motor)
32 Stator
33 Rotor
34 Output shaft
34a Gear portion
35, 36 Bearing
37 Hall IC (magnetic sensor)
38 Hall IC board
41 Crank shaft
42 Pinion gear
43 Eccentric member
44 Crank pin
45 Connecting rod
46 Piston pin
47 Motion conversion mechanism
51 Rotational force transmission shaft
52, 53 Pinion gear
54 Driven sleeve
55, 56 Bevel gear
57 Coil spring
58 Feed cable
59 Trigger
59a Trigger switch
64 Connector
64a Rubber cap (cover member)
65 Inverter circuit
66 AC power supply
67 Diode bridge (rectifying circuit)
68 Inverter temperature detection element
69 Motor temperature detection element
72 Microcomputer (control unit)
73 Control signal output circuit
74 Hall IC signal detection circuit
75 External communication circuit (communication means)
76 Motor current detection circuit
77 Trigger switch detection circuit
78 Motor temperature detection circuit
79 Cooling fan
80 Intermediate case
81 Suction hole
82 Exhaust hole
83 Input voltage detection circuit
84 Rectification voltage detection circuit
85 Control circuit voltage supply circuit
86 Inverter temperature detection circuit
87 Battery
100 Diagnosis device
101 CPU (control unit)
102 Memory (storage unit)
103 Input device
104 Output device
105 External device communication unit (communication means)
106 Power supply circuit
107 Connector
108 Cable
T Tool
301 Management system
302 Instrument
321 First storage unit
303 Intermediate device
331 to 334 Control unit
335 Display screen
336 Diagnosis start button
337 End button
338 Repair history button
304 Management device (server)
341 Second storage unit
350 Display screen
351 Unique ID input portion
352 Retrieval start button
353 End button
354 Display portion

1. A failure diagnosis system comprising:
an electric tool having a function of storing usage history information thereof; and
a diagnosis device capable of being connected to the electric tool,
wherein the diagnosis device is configured to:
reads out the usage history information of the electric tool from the electric tool being connected,
estimates a failure part of the electric tool and a cause of a defect on the basis of the usage history information, and
reports information indicating the failure part and the cause of the defect.

2. The failure diagnosis system according to claim 1,
wherein the usage history information includes at least one of a motor operation time, the number of operations of a motor driving switch, a power supply voltage, a motor current, a motor temperature, a temperature of a motor driving circuit, whether or not a motor is able to be driven, presence or absence of a high-temperature abnormality, presence or absence of an overcurrent abnormality, presence or absence of an overvoltage abnormality, and an output signal of a sensor that detects a rotational position of the motor.

3. The failure diagnosis system according to claim 1,
wherein the electric tool includes a brushless motor, an inverter circuit for electrical conduction to the brushless motor, and a control unit that controls the inverter circuit.

4. The failure diagnosis system according to claim 3,
wherein the diagnosis device estimates a constituent part of the electric tool to be out of order in a case where the usage history information indicates one or both of the following (1) and (2),
(1) the inverter circuit is estimated to be out of order in a case where it is indicated that the brushless motor is not able to be driven, an overcurrent abnormality is present, and a motor operation time exceeds a predetermined time, and
(2) the filter circuit is estimated to be out of order in a case where the electric tool is AC-driven and has a filter circuit, and a case where it is indicated that the brushless motor is able to be driven and an overvoltage abnormality is present.

5. The failure diagnosis system according to claim 1,
wherein the diagnosis device displays at least one of the following (1) to (4) on a screen,
(1) a button for a user to give an instruction for starting of diagnosis for the electric tool being connected,
(2) product information, presence or absence of a failure, and a failure estimation part of a connected electric tool,
(3) a cause of a defect in the electric tool being connected, and
(4) usage history information of the electric tool being connected.

6. The failure diagnosis system according to claim 1,
wherein the diagnosis device is capable of being connected to the electric tool in a wired manner through a connector for cable connection facing outside from a housing of the electric tool, or is capable of being wirelessly connected to the electric tool.

7. The failure diagnosis system according to claim 1,
wherein the diagnosis device is a general-purpose computer.

8.-15. (canceled)
